(19) United States
(12) Patent Application Publication
(10) Pub. No.: US 2026/0279756 A1
(43) Pub. Date: Sep. 17, 2026

(54) UV LIGHT IRRADIATION APPARATUS AND MOUNTING SYSTEM

(71) Applicant: SHIBAURA MECHATRONICS CORPORATION, Yokohama-shi (JP)

(72) Inventors: Naoki SETO, Yokohama-shi (JP); Takuya OHE, Yokohama-shi (JP); Kyota KUROIWA, Yokohama-shi (JP)

(73) Assignee: SHIBAURA MECHATRONICS CORPORATION, Yokohama-shi (JP)

(21) Appl. No.: 19/547,991

(22) Filed: Feb. 24, 2026

(30) Foreign Application Priority Data
Mar. 11, 2025 (JP) 2025-038011
Dec. 18, 2025 (JP) 2025-265786

(51) Int. Cl. H01J 61/30; H01J 61/36; H01J 65/08

(52) U.S. Cl. CPC H01J 61/30; H01J 61/361; H01J 65/08

(57) ABSTRACT

According to an embodiment, a UV light irradiation apparatus is an apparatus for irradiating UV light onto a resin film with multiple electronic components adhered to a first surface of the resin film. The UV light irradiation apparatus includes a support stage for supporting the resin film; a gas supply portion for supplying inert gas from a gas discharge portion facing the support stage to the first surface of the resin film; and a light source portion irradiating UV light onto a second surface of the resin film opposite the first surface.

### CROSS-REFERENCE TO RELATED APPLICATIONS

This application claims the benefit of priority to Japanese Patent Application No. 2025-038011, filed on Mar. 11, 2025, and No. 2025-265786 filed on Dec. 18, 2025, the entire contents of which are incorporated herein by reference.

### BACKGROUND

### Technical Field

One embodiment of the present disclosure relates to a UV light (ultraviolet light) irradiation apparatus and mounting system including the UV light irradiation apparatus.

### Description of the Related Art

Conventionally, as a method for mounting an electronic component such as a semiconductor chip on a substrate and connecting electrodes of the electronic component to electrodes of the substrate, a bonding method using bonding members such as wires or bumps has been known. In recent years, with the increasing density of integrated circuits, a method of directly bonding electronic components to electrodes on a substrate without using a bonding member, such as hybrid bonding, has been attracting attention. In such a direct bonding technique, for example, when bonding a semiconductor chip, which is an electronic component, to a semiconductor wafer, which is a substrate, first, a surface activation treatment (e.g., plasma treatment) is performed on the bonding surfaces of the semiconductor chip and the semiconductor wafer to add hydroxyl groups to an insulating film on each bonding surface (terminating the insulating film with hydroxyl groups). Subsequently, the bonding surfaces of the semiconductor chip and the semiconductor wafer are brought into contact with each other to perform a temporary bonding. Finally, heating is performed to firmly bond the insulating films together (main bonding) and to diffusion bond the electrodes together to establish an electrical connection.

For example, in the process of mounting the semiconductor chip on the semiconductor wafer, the semiconductor chip is supplied in a state adhered to an adhesive resin film (adhesive tape) called a wafer sheet, dicing tape, etc. In this case, the semiconductor chip is in a state of being singulated from the semiconductor wafer. Then, various treatments, such as cleaning and surface activation, are performed on the semiconductor chip on the adhesive tape. Subsequently, the adhesive strength of the adhesive tape is reduced, and each semiconductor chip is mounted on another semiconductor chip or semiconductor wafer, which is the mounting target, by a bonding apparatus. The adhesive strength of the adhesive tape is reduced by curing an adhesive layer on the surface. Usually, a UV-curable resin is used as the material for the adhesive layer. In other words, by irradiating the adhesive layer with UV light, the adhesive strength is reduced, and the adhered semiconductor chip can be easily removed.

However, acrylic UV-curable resins, which are widely used in adhesive tapes, have the characteristic that their curing reaction is impaired in the presence of oxygen. This phenomenon is called oxygen inhibition and occurs when radicals generated by irradiation with UV light combine with oxygen, suppressing the curing reaction. Therefore, even when UV light is irradiated onto the adhesive tape, the surface of the adhesive layer exposed to oxygen does not cure due to oxygen inhibition, maintaining its adhesive strength. That is, the vicinity of the outer edge of the semiconductor chip remains firmly attached (adhered) to the adhesive layer. In such a state, if an attempt is made to remove the semiconductor chip from the adhesive tape using a pickup mechanism, unnecessary force may be applied to the semiconductor chip, which may cause damage such as cracks or chips to the semiconductor chip. In addition, residues from the adhesive layer may remain on the removed semiconductor chip, which may become waste, such as particles, in subsequent processes, potentially reducing yield.

### BRIEF SUMMARY

The UV light irradiation apparatus according to an embodiment of the present disclosure includes a support stage for supporting a resin film; a gas supply portion for supplying inert gas from a gas discharge portion facing the support stage to a first surface of the resin film; and a light source portion irradiating UV light onto a second surface of the resin film opposite the first surface.

### BRIEF DESCRIPTION OF THE SEVERAL VIEWS OF THE DRAWINGS

FIG. 1 is a block diagram showing an overall configuration of a mounting system according to an embodiment of the present disclosure.

FIG. 2A is a diagram showing a configuration of a supply substrate, which is a treatment target of a mounting system according to an embodiment of the present disclosure.

FIG. 2B is a diagram showing a configuration of a supply substrate, which is a treatment target of a mounting system according to an embodiment of the present disclosure.

FIG. 2C is a diagram showing a configuration of an adhesive tape, which is a treatment target of a mounting system according to an embodiment of the present disclosure.

FIG. 3 is a schematic cross-sectional view showing a configuration of a UV light irradiation unit according to an embodiment of the present disclosure.

FIG. 4 is a diagram showing a state in which a supply substrate is loaded into a UV light irradiation unit according to an embodiment of the present disclosure.

FIG. 5 is a diagram showing a state in which a descent of a gas supply unit has started in a UV light irradiation unit according to an embodiment of the present disclosure.

FIG. 6 is a diagram showing a state in which a descent of a gas supply unit is completed in a UV light irradiation unit according to an embodiment of the present disclosure.

FIG. 7 is a diagram showing a state in which UV light is irradiated from a light source unit in a UV light irradiation unit according to an embodiment of the present disclosure.

FIG. 8 is a diagram showing a state in which UV light is irradiated from a light source unit in a UV light irradiation unit according to an embodiment of the present disclosure.

FIG. 9 is a diagram showing a state in which UV light is irradiated from a light source unit in a UV light irradiation unit according to an embodiment of the present disclosure.

FIG. 10 is a diagram showing a state in which UV light is irradiated from a light source unit in a UV light irradiation unit according to an embodiment of the present disclosure.

FIG. 11 is a diagram showing a state in which UV light is irradiated from a light source unit in a UV light irradiation unit according to an embodiment of the present disclosure.

FIG. 12A is a diagram showing a state in which UV light is irradiated from a light source unit in a UV light irradiation unit according to an embodiment of the present disclosure.

FIG. 12B is a diagram showing a state in which UV light is irradiated from a light source unit in a UV light irradiation unit according to an embodiment of the present disclosure.

FIG. 13 is a diagram showing a state in which UV light is irradiated from a light source unit in a UV light irradiation unit according to an embodiment of the present disclosure.

FIG. 14 is a plan view showing a configuration of a gas supply unit in a UV light irradiation unit according to an embodiment of the present disclosure.

FIG. 15A is a schematic diagram showing a configuration of a gas discharge portion in a gas supply unit according to an embodiment of the present disclosure.

FIG. 15B is a schematic diagram showing a configuration of a gas discharge portion in a gas supply unit according to an embodiment of the present disclosure.

FIG. 16A is a schematic diagram showing a configuration of a gas discharge portion in a gas supply unit according to an embodiment of the present disclosure.

FIG. 16B is a schematic diagram showing a configuration of a gas discharge portion in a gas supply unit according to an embodiment of the present disclosure.

FIG. 17A is a diagram showing a state in which UV light is irradiated from a light source unit in a UV light irradiation unit according to an embodiment of the present disclosure.

FIG. 17B is a bottom view of a head portion of a gas supply unit according to an embodiment of the present disclosure.

FIG. 18A is a diagram showing a state in which UV light is irradiated from a light source unit in a UV light irradiation unit according to an embodiment of the present disclosure.

FIG. 18B is a top view of a light source unit according to an embodiment of the present disclosure.

FIG. 19 is a block diagram showing an overall configuration of a mounting system according to an embodiment of the present disclosure.

### DETAILED DESCRIPTION

Hereinafter, a UV light irradiation apparatus according to an embodiment of the present disclosure will be described with reference to the drawings. However, the UV light irradiation apparatus to which the present disclosure is applied can be implemented in many different forms and is not limited to the examples described below.

In the specification and claims of the present disclosure, “up” indicates a direction vertically away from an installation surface of the UV light irradiation apparatus (for example, a floor of a factory) in a state in which the UV light irradiation apparatus is installed for normal use, and “down” indicates a direction opposite to “up” (usually the direction of gravity). “Inside” indicates a direction toward the center of the UV light irradiation apparatus, and “outside” indicates a direction opposite to “inside”. In addition, “up-down direction” is synonymous with “vertical direction,” and “left-right direction” is synonymous with “horizontal direction.”

### First Embodiment

### Configuration of Mounting System 1

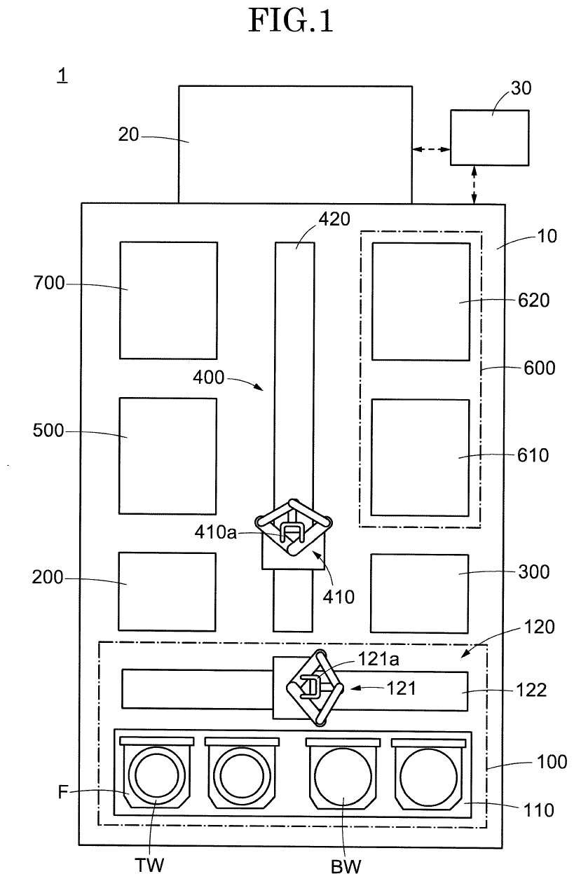

FIG. 1 is a block diagram showing an overall configuration of a mounting system 1 according to an embodiment of the present disclosure. For example, the mounting system 1 is an apparatus arranged in a factory for manufacturing a semiconductor integrated circuit and is used to mount electronic components, such as a semiconductor chip, on a substrate (mounting substrate) such as a semiconductor wafer. Specifically, the mounting system 1 of the present embodiment is a C2W (Chip to Wafer) mounting system that uses direct bonding technology to mount the semiconductor chip on the semiconductor wafer. In addition, the semiconductor wafer as the mounting substrate may be, for example, an interposer substrate with through electrodes formed in the semiconductor wafer, a circuit substrate with integrated circuits formed in the semiconductor wafer by a semiconductor process, or a circuit substrate with a plurality of semiconductor chips mounted on the semiconductor wafer.

In FIG. 1, when direct bonding is performed, a pretreatment apparatus 10 performs a surface activation treatment and a cleaning treatment on the bonding surfaces of the mounting substrates, such as the semiconductor chip and the semiconductor wafer. In addition, the pretreatment apparatus 10 performs pretreatment for mounting, such as UV light irradiation treatment, which irradiates the adhesive tape with UV light to reduce or eliminate the adhesive strength, so that the semiconductor chip can be easily picked up from the adhesive tape that supports the semiconductor chip. A bonding apparatus 20 mounts (places, loads, or temporarily bonds) the semiconductor chip that has been pretreated by the pretreatment apparatus 10 onto the mounting substrate that has also been pretreated. In addition, when direct bonding is not performed, the bonding apparatus 20 mounts (places, loads, or temporarily bonds) chips that have not been pretreated by the pretreatment apparatus onto the mounting substrate that has not been pretreated.

The mounting system 1 of the present embodiment includes the pretreatment apparatus 10 and the bonding apparatus 20 that mounts the electronic components received from the pretreatment apparatus 10 onto the substrate. The pretreatment apparatus 10 and the bonding apparatus 20 are controlled by a control unit 30 that is communicatively connected to the pretreatment apparatus 10 and the bonding apparatus 20. Therefore, the mounting system 1 of the present embodiment includes the pretreatment apparatus 10, the bonding apparatus 20, and the control unit 30.

The pretreatment apparatus 10 is an apparatus for performing pretreatment for direct bonding, such as activation treatment and cleaning treatment of the bonding surface, and treatment to reduce the adhesive strength of the adhesive tapes (UV light irradiation treatment) on a supply substrate TW and a mounting substrate BW, which are the treatment targets. The specific configuration of the pretreatment apparatus 10 will be described later.

The supply substrate TW is a substrate for transporting the electronic components (semiconductor chips) to be mounted on the mounting substrate BW (the semiconductor wafer) so that the electronic components can be treated by the mounting system 1. Specifically, the supply substrate TW is a substrate having a structure in which a plurality of singulated semiconductor chips is attached (adhered) to the adhesive tape supported by a frame.

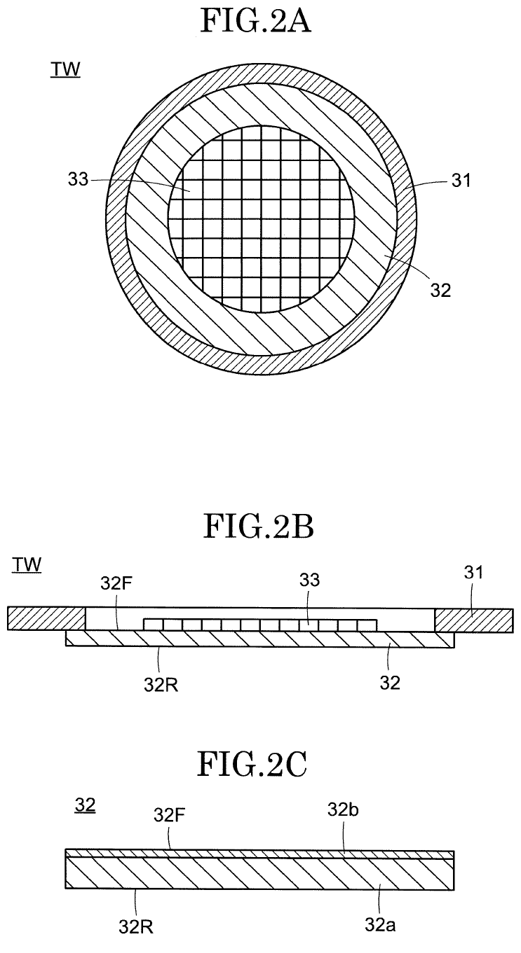

FIG. 2A and FIG. 2B are diagrams showing configurations of the supply substrate TW, which is the treatment target of the mounting system 1 according to an embodiment of the present disclosure. FIG. 2A is a plan view of the supply substrate TW, and FIG. 2B is a cross-sectional view of the supply substrate TW seen from the side. As shown in FIG. 2A, the supply substrate TW includes a frame 31, an adhesive tape 32 supported by the frame 31, and a plurality of semiconductor chips 33 adhered to the adhesive tape 32.

The frame 31 is an annular frame made of stainless steel or the like, and is called a dicing frame, a tape frame, or the like. As shown in FIG. 2A and FIG. 2B, the adhesive tape 32 has its outer edge attached to the frame 31 and is supported to cover an opening of the frame 31. The plurality of semiconductor chips 33 is attached to a surface (first surface 32F) of the adhesive tape 32. The plurality of semiconductor chips 33 is formed by singulating the semiconductor wafer (the semiconductor wafer with integrated circuits formed) attached to the adhesive tape 32. Furthermore, in the following description, the back surface of the adhesive tape (the surface opposite to the first surface 32F) is referred to as a second surface 32R.

FIG. 2C is a diagram showing a configuration of the adhesive tape 32 of the supply substrate TW, which is the treatment target of the mounting system 1 according to an embodiment of the present disclosure. The adhesive tape 32 is an adhesive tape formed by stacking resin layers. Specifically, the adhesive tape 32 is formed by stacking a first resin layer 32a as a base material and a second resin layer 32b as an adhesive layer. The adhesive tape 32 is attached to the frame 31 by the adhesiveness of the surface of the second resin layer 32b. That is, the plurality of semiconductor chips 33 is adhered to the surface of the second resin layer 32b (corresponding to the first surface 32F). The UV light irradiation apparatus described later irradiates the second resin layer 32b with UV light to cure the second resin layer 32b and reduce the adhesiveness. That is, the second resin layer 32b is composed of the UV-curable resin. The first resin layer 32a is composed of a resin that transmits UV light, and the UV light is irradiated onto the back surface (corresponding to the second surface 32R) of the first resin layer 32a. That is, the second resin layer 32b is cured by being irradiated with the UV light that has passed through the first resin layer 32a.

Returning to the explanation of FIG. 1, the bonding apparatus 20 is an apparatus that mounts the semiconductor chip, whose bonding surface has been activated by the pretreatment apparatus 10, onto the mounting substrate BW. Since the mounting system 1 integrates the pretreatment apparatus 10 and the bonding apparatus 20, the supply substrate TW and the mounting substrate BW, whose bonding surfaces have been activated by the pretreatment apparatus 10, can be transferred continuously to the bonding apparatus 20 without delay. Therefore, direct bonding can be performed before the active states of the bonding surfaces of the semiconductor chip and the semiconductor wafer deteriorate, and a decrease in strength during bonding can be prevented.

The control unit 30 controls the pretreatment apparatus 10 and the bonding apparatus 20. The control unit 30 includes a storage unit and a processor. The storage unit stores a control program for controlling the operations of the pretreatment apparatus 10 and the bonding apparatus 20, as well as various control data for executing the control program. The processor controls the pretreatment apparatus 10 and the bonding apparatus 20 by reading and executing the control program described above from the storage unit. The control unit 30 may include a display device, such as a touch panel, as a user interface for receiving an input from an operator controlling the mounting system 1.

### Configuration of Pretreatment Apparatus 10

The pretreatment apparatus 10 includes a load/unload unit 100, a supply buffer unit 200, a discharge buffer unit 300, a workpiece transport unit 400, an activation processing unit 500, a cleaning unit 600, and a UV light irradiation unit 700. However, the configuration of the pretreatment apparatus 10 is not limited to this example, and some components shown in FIG. 1 may be omitted, or other components may be added.

The load/unload unit 100 handles the transportation of a workpiece such as the supply substrate TW and the mounting substrate BW between the mounting system 1 and the outside. The workpiece received from outside the mounting system 1 before mounting processing is temporarily held in the supply buffer unit 200. In addition, the workpiece to be discharged to the outside of the mounting system 1 after the mounting processing is held in the discharge buffer unit 300. The supply substrate TW and the mounting substrate BW supplied into the mounting system 1 before mounting processing are subjected to an activation processing of the bonding surfaces in the activation processing unit 500. The workpiece after the activation processing is cleaned in the cleaning unit 600. The UV light irradiation unit 700 irradiates UV light onto the cleaned supply substrate TW, reducing the adhesive strength of the adhesive tape, on which the electronic components such as semiconductor chips are mounted. The workpiece transport unit 400 transports the workpiece to each processing unit such as the activation processing unit 500 and the UV light irradiation unit 700.

The load/unload unit 100 is an apparatus for transporting the workpiece, such as the supply substrate TW and the mounting substrate BW, and includes a container installation unit 110 and a workpiece transport unit 120. In the present embodiment, a so-called EFEM (Equipment Front End Module) is used as the load/unload unit 100.

The container installation unit 110 is a platform for installing a workpiece transport container F called a FOUP (Front-Opening Unified Pod). The workpiece transport container F accommodates workpieces (the supply substrate TW and the mounting substrate BW) supplied to the pretreatment apparatus 10, or workpieces (mounted substrates) discharged from the pretreatment apparatus 10. In the example shown in FIG. 1, four workpiece transport containers F are lined up in the container installation unit 110. Specifically, the two workpiece transport containers F on the left side accommodate the supply substrate TW, and the two on the right side accommodate the mounting substrate BW. After being used in the mounting process, the supply substrate TW is returned to an empty slot in the workpiece transport container F that accommodates the supply substrate TW before the mounting processing. Similarly, the mounted substrate BW after the mounting processing is returned to an empty slot in the workpiece transport container F that accommodates the mounting substrate BW before the mounting processing.

The workpiece transport unit 120 includes a transport robot 121 and a moving mechanism 122. The transport robot 121 is a robot that handles workpieces and transports workpieces using a transport arm 121a. The moving mechanism 122 is a mechanism for moving the transport robot 121 and positioning the transport robot 121. Specifically, the moving mechanism 122 adjusts the position of the transport robot 121 to match the position of the workpiece transport container F installed in the container installation unit 110, the supply buffer unit 200, and the discharge buffer unit 300, which will be described later.

The supply buffer unit 200 is a unit for temporarily holding the workpieces before the mounting processing. For example, the supply buffer unit 200 can temporarily hold the workpieces (the supply substrate TW and the mounting substrate BW) supplied to the pretreatment apparatus 10 by the load/unload unit 100 until the workpieces are transported by the workpiece transport unit 400 described later. The supply buffer unit 200 may be configured to hold a plurality of workpieces.

The discharge buffer unit 300 is a unit for temporarily holding the workpieces after the mounting processing. Specifically, the workpieces (mounted substrates) on which the semiconductor chip has been mounted by the bonding apparatus 20 are temporarily held. For example, the discharge buffer unit 300 can temporarily hold the workpieces discharged from the bonding apparatus 20 until the workpieces are transported by the workpiece transport unit 120 of the load/unload unit 100. The discharge buffer unit 300 may be configured to hold a plurality of workpieces. In addition, the discharge buffer unit 300 can temporarily hold the supply substrate TW on which some semiconductor chips remain when the supply substrate TW is temporarily returned to the workpiece transport container F.

The workpiece transport unit 400 is an apparatus for transporting workpieces to each processing unit such as the activation processing unit 500 and the UV light irradiation unit 700, and includes a transport robot 410 and a moving mechanism 420. The transport robot 410 is a robot that handles workpieces and transports workpieces using a transport arm 410a. The moving mechanism 420 is a mechanism for moving the transport robot 410 and positioning the transport robot 410. Specifically, the moving mechanism 420 adjusts the position of the transport robot 410 to match the position of each processing unit.

The activation processing unit 500 is an apparatus (plasma treatment device) for performing processing to activate the bonding surfaces of the semiconductor chips included in the supply substrate TW. Specifically, the activation processing unit 500 performs plasma treatment on the bonding surfaces of the semiconductor chips. In the present embodiment, nitrogen gas is used as the gas used in the plasma treatment. However, the present disclosure is not limited to this example, and an inert gas other than nitrogen gas (for example, argon gas, helium gas, neon gas) may be used as the gas used in the plasma treatment. In addition, the gas used in the plasma treatment is not limited to an inert gas, and oxygen gas, hydrogen gas, or water vapor may also be used. By using these gases, cleaning to remove organic substances from the bonding surfaces can be performed, and activation to remove oxide films formed on the bonding surfaces and terminate the insulating films on the bonding surfaces with hydroxyl groups can be performed. In particular, it is preferable to include water vapor during the plasma treatment, as it allows for efficient termination of the insulating film on the bonding surfaces with hydroxyl groups. In addition, when performing pretreatment for direct bonding, the activation processing unit 500 performs activation processing not only on the bonding surfaces of the semiconductor chips in the supply substrate TW but also on the bonding surfaces of the mounting substrate BW (for example, semiconductor wafer).

The cleaning unit 600 is an apparatus (cleaning apparatus) for cleaning workpieces. In the present embodiment, the cleaning unit 600 includes a supply-substrate cleaning unit 610 and a mounting-substrate cleaning unit 620. The supply-substrate cleaning unit 610 is an apparatus for cleaning the supply substrate TW, and the mounting-substrate cleaning unit 620 is an apparatus for cleaning the mounting substrate BW. Since the supply substrate TW and the mounting substrate BW may have different sizes (diameters), the throughput can be improved by providing dedicated devices for each. However, the present disclosure is not limited to this example, and a configuration may be adopted in which one cleaning apparatus handles both the cleaning of the supply substrate TW and the mounting substrate BW.

The supply-substrate cleaning unit 610 and the mounting-substrate cleaning unit 620 are composed of cleaning apparatuses that perform spin cleaning of workpieces. In the present embodiment, after the plasma treatment is performed on the supply substrate TW and the mounting substrate BW in the activation processing unit 500, the supply substrate TW and the mounting substrate BW are cleaned in the supply-substrate cleaning unit 610 and the mounting-substrate cleaning unit 620, respectively. As a result, the bonding surfaces of the semiconductor chip and the semiconductor wafer are efficiently terminated with hydroxyl groups, making them suitable for direct bonding.

The UV light irradiation unit 700 is an apparatus (the UV light irradiation apparatus) for irradiating UV light onto the supply substrate TW. The UV light irradiation unit 700 has a function of reducing the adhesive strength of the adhesive tape by irradiating UV light onto the adhesive tape to which the semiconductor chip is adhered to the supply substrate TW. This makes it easier to remove the semiconductor chip from the adhesive tape when picking it up from the supply substrate TW in the bonding apparatus 20. Details of the UV light irradiation unit 700 will be described below.

### Configuration of UV Light Irradiation Unit 700

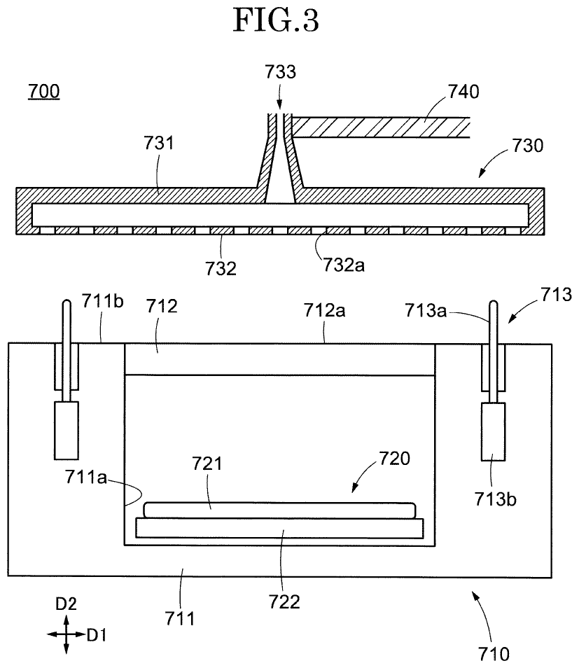

FIG. 3 is a schematic cross-sectional view showing a configuration of the UV light irradiation unit 700 according to an embodiment of the present disclosure. The UV light irradiation unit 700 is the UV light irradiation apparatus for irradiating UV light onto the resin film (the adhesive tape 32) to which a plurality of electronic components (the semiconductor chip 33) is adhered to the first surface (front surface). As shown in FIG. 3, the UV light irradiation unit 700 includes a support stage 710, a light source unit 720, and a gas supply unit 730. However, the configuration of the UV light irradiation unit 700 is not limited to this example, and some components shown in FIG. 3 may be omitted, or other components may be added. Furthermore, in FIG. 3 and subsequent figures, a direction D1 indicates the left-right direction (horizontal direction), and a direction D2 indicates the up-down direction (vertical direction).

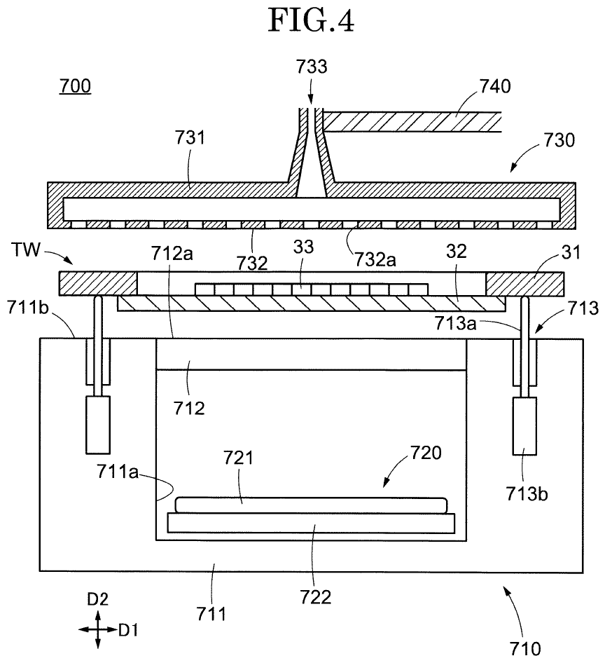

The support stage 710 includes a housing 711, a light-transmitting member 712, and a plurality of push-pull mechanisms 713. However, the configuration of the support stage 710 is not limited to this example, and some components shown in FIG. 3 may be omitted, or other components may be added. The housing 711 is a member that serves as the base of the support stage 710 and functions as a pedestal to support the supply substrate TW. The housing 711 is arranged so that the light-transmitting member 712, which transmits UV light, faces a gas discharge portion 732 of the gas supply unit 730. For example, quartz can be used as the light-transmitting member 712. As shown in FIG. 3, the light-transmitting member 712 is arranged so that a flat surface supporting the supply substrate TW is formed by an upper surface 711b of the housing 711 and an upper surface 712a of the light-transmitting member 712. In the present embodiment, an opening 711a is provided in the housing 711, and the light-transmitting member 712 is fitted inside the upper end of the opening 711a, but the present disclosure is not limited to this example. For example, in the case where the supply substrate TW can be supported by supporting the frame 31, the light-transmitting member 712 may be omitted. As shown in FIG. 3, the opening 711a is provided to face the gas discharge portion 732 (or the supply substrate TW placed on the housing 711 as shown in FIG. 4, described later).

Each push-pull mechanism 713 includes a support pin 713a and a pin drive unit 713b that moves the support pin 713a in the up-down direction, and is arranged around the opening 711a. As shown in FIG. 3, the push-pull mechanism 713 has a function of supporting the supply substrate TW when the supply substrate TW is placed on the support stage 710. Therefore, although not shown, in the present embodiment, four push-pull mechanisms 713 are arranged around the opening 711a at positions symmetrical to the center of the opening 711a. However, the arrangement of the push-pull mechanism 713 is not limited to this example, and the push-pull mechanism 713 may be arranged in any manner as long as it is able to support the supply substrate TW. Furthermore, in the present embodiment, the support pin 713a is provided to contact and support the frame 31 of the supply substrate TW (see FIG. 4).

The light source unit 720 is arranged below the light-transmitting member 712 and has a function of irradiating UV light upward. The light source unit 720 includes a light source 721 and a light source drive portion 722 that drives the light source 721. In the present embodiment, an LED that emits UV light is used as the light source 721. However, the present disclosure is not limited to this example, and the light source 721 may be a UV lamp that emits UV light. The light source drive portion 722 may include a power supply circuit and a driving circuit for causing the light source 721 to emit light.

In the present embodiment, a surface light source is used as the light source 721, and a configuration is adopted in which UV light can be irradiated onto the adhesive tape of the supply substrate TW at once, but the present disclosure is not limited to this example. For example, a linear light source may be used as the light source 721, and by scanning the light source 721 in one direction, UV light can be irradiated from one end to the other end of the adhesive tape of the supply substrate TW. In this case, the light source drive portion 722 may include a moving mechanism (for example, an actuator) for scanning the light source 721, in addition to the power supply circuit and the driving circuit described above.

Although not shown, the light source unit 720 may have an optical system for changing the irradiation direction of UV light or processing the shape of UV light. For example, in the example shown in FIG. 3, although the configuration in which the light source 721 is arranged below the light-transmitting member 712 is exemplified, the present disclosure is not limited to this example, and the light source 721 may be arranged at a position other than below the light-transmitting member 712, and UV light may be guided to the light-transmitting member 712 using the optical system. In addition, when the light source 721 is scanned to irradiate UV light, an optical system may be provided to process the shape of the UV light emitted from the light source 721, which is configured by the linear light source, into a rectangular shape or other shape.

The gas supply unit 730 is arranged above the support stage 710 and has a function of discharging an inert gas (in this case, nitrogen gas) downward. The gas supply unit 730 includes a head portion 731 to which an inert gas is supplied, the gas discharge portion 732 that discharges the inert gas from inside the head portion 731, and a supply port 733 that supplies the inert gas from the outside (factory equipment, etc.) to the inside of the head portion 731 via a pipe (not shown). FIG. 3 shows a cross-section, but the head portion 731 has a substantially circular outer shape in a plan view. The gas discharge portion 732 is provided with a plurality of openings 732a through which the inert gas is discharged. That is, the gas supply unit 730 of the present embodiment functions as a gas nozzle that discharges the inert gas downward, like a showerhead.

In the gas supply unit 730, the gas discharge portion 732 is provided to face the support stage 710. The gas discharge portion 732 may be composed of, for example, a shower plate having a substantially circular outer shape, and the inert gas supplied to the inside of the head portion 731 is discharged through the plurality of openings 732a onto the supply substrate TW placed on the support stage 710. Therefore, the gas supply unit 730 can supply the inert gas uniformly toward the supply substrate TW. Furthermore, in the present embodiment, although an example is shown in which the gas discharge portion 732 is composed of a shower plate having a substantially circular outer shape, the present disclosure is not limited to this example, and the outer shape of the gas discharge portion 732 in a plan view may be another shape.

The size of the gas discharge portion 732 is preferably large enough to cover the entire surface side of the supply substrate SW placed on the support stage 710 with an inert gas. Specifically, the gas discharge portion 732 is preferably large enough to cover at least the surface (the first surface 32F) of the adhesive tape 32 (more preferably, large enough to cover the entire frame 31).

In addition, the gas supply unit 730 is movable in the direction D2, that is, in the up-down direction (a direction approaching the support stage 710 and a direction away from the support stage 710). For example, a lifting mechanism 740 is connected to the gas supply unit 730, and the gas supply unit 730 can be moved in the up-down direction by driving the lifting mechanism 740. In practice, since the supply substrate TW is placed on the support stage 710, it can be said that the gas supply unit 730 is movable in a direction approaching the supply substrate TW and a direction away from the supply substrate TW. The gas supply unit 730 can move between a standby position and a processing position by moving in the up-down direction. The standby position (home position) is a position that does not interfere with the transport arm 410a (see FIG. 1) and the supply substrate TW when the supply substrate TW is loaded into or out of the support stage 710. The processing position is a position at which an inert gas is discharged from the gas discharge portion 732 onto the supply substrate TW, and is a position at a predetermined height (specifically, a height of 1 mm or more and 10 mm or less) from the supply substrate TW. In other words, the gas supply unit 730 is positioned at a height that does not interfere with the transport arm 410a (see FIG. 1) and the supply substrate TW when the supply substrate TW is loaded into or out of the support stage 710, and moves to the processing position after the supply substrate TW is placed on the support stage 710.

### Operation of UV Light Irradiation Unit 700

Next, an operation of the UV light irradiation treatment in the UV light irradiation unit 700 will be described. Specifically, the operation from carrying the supply substrate TW into the UV light irradiation unit 700 to irradiating UV light onto the supply substrate TW will be described.

FIG. 4 is a diagram showing a state in which the supply substrate TW is carried into the UV light irradiation unit 700 according to an embodiment of the present disclosure. When setting the supply substrate TW in the UV light irradiation unit 700, the transport robot 410 shown in FIG. 1 transports the supply substrate TW onto the support stage 710 with the supply substrate TW placed on the transport arm 410a. Therefore, in the state shown in FIG. 3, the gas supply unit 730 is retracted to the home position, and the push-pull mechanism 713 moves the support pin 713a upward. The transport robot 410 transports the supply substrate TW onto the support stage 710, and then aligns the frame 31 of the supply substrate TW to rest on the support pin 713a. Thereafter, the transport robot 410 lowers the transport arm 410a to place the supply substrate TW on the support pin 713a. When the supply substrate TW is placed on the support pin 713a, the transport robot 410 retracts the transport arm 410a, completing the loading of the supply substrate TW. As a result, as shown in FIG. 4, the supply substrate TW is in a state supported by the plurality of push-pull mechanisms 713.

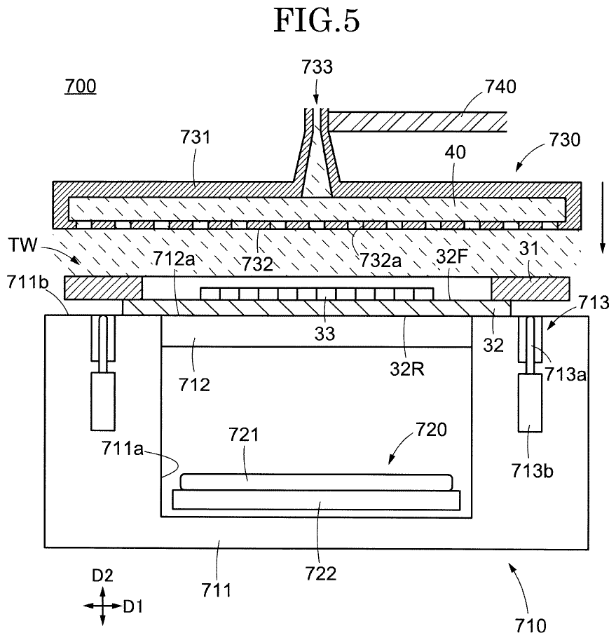

FIG. 5 is a diagram showing a state in which a descent of the gas supply unit 730 has started in the UV light irradiation unit 700 according to an embodiment of the present disclosure. In the state shown in FIG. 5, the support pin 713a has been moved downward by the push-pull mechanism 713, so that the supply substrate TW is placed on the support stage 710. That is, the supply substrate TW is placed on a flat surface formed by the upper surface 711b of the housing 711 of the support stage 710 and the upper surface 712a of the light-transmitting member 712.

In addition, the gas supply unit 730 begins to move downward after the supply substrate TW is placed on the support stage 710. As shown in FIG. 5, while the gas supply unit 730 is descending, an inert gas 40 is supplied from the supply port 733 into the inside of the head portion 731. As a result, the gas supply unit 730 descends while pushing the air present in a space between the gas discharge portion 732 and the supply substrate TW (specifically, the first surface 32F of the adhesive tape 32) sideways with the inert gas 40.

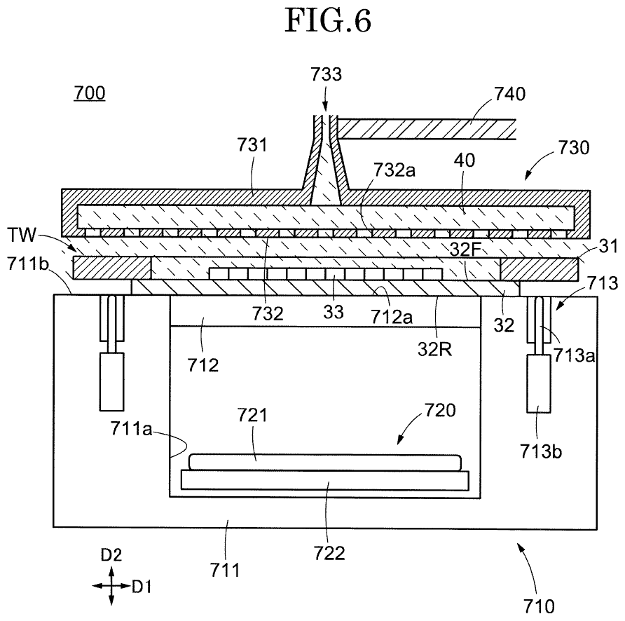

FIG. 6 is a diagram showing a state in which a descent of the gas supply unit 730 is completed in the UV light irradiation unit 700 according to an embodiment of the present disclosure. Specifically, FIG. 6 shows a state in which the gas supply unit 730 is lowered until the distance between the gas discharge portion 732 and the supply substrate TW (specifically, the frame 31) becomes 1 mm or more and 10 mm or less (preferably, 3 mm or more and 7 mm or less).

In the state shown in FIG. 6, a space between the gas discharge portion 732 and the first surface 32F of the adhesive tape 32 is filled with the inert gas 40. That is, in the state shown in FIG. 6, the oxygen present on the first surface 32F of the adhesive tape 32 (specifically, the surface of the second resin layer 32b shown in FIG. 2C) is completely replaced by the inert gas 40 (i.e., nitrogen gas). In this way, the gas supply unit 730 of the present embodiment can maintain the space between the gas discharge portion 732 and the first surface 32F of the adhesive tape 32 in an inert atmosphere. In addition, continuing to discharge the inert gas 40 even after the descent of the gas discharge portion 732 has completed is preferable for efficiently replacing the gas in contact with the first surface 32F of the adhesive tape 32 with the inert gas 40.

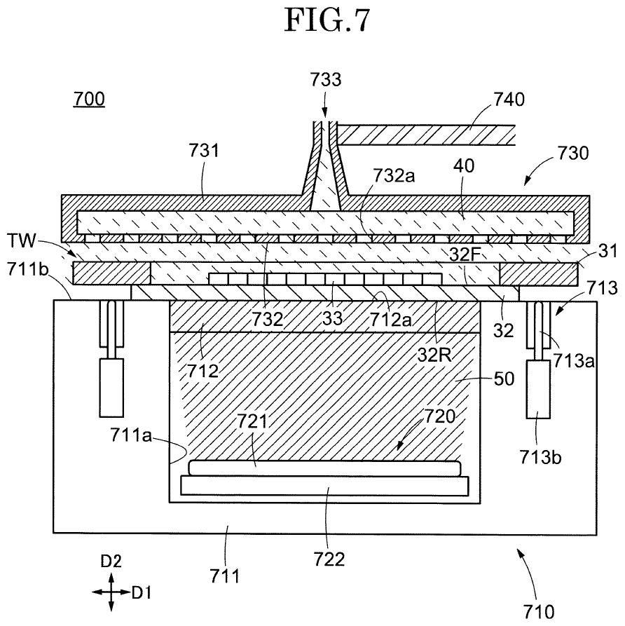

FIG. 7 is a diagram showing a state in which a UV light 50 is irradiated from the light source unit 720 in the UV light irradiation unit 700 according to an embodiment of the present disclosure. Specifically, FIG. 7 shows a state in which the UV light 50 is irradiated from the light source 721 onto the back surface (the second surface 32R) of the adhesive tape 32 of the supply substrate TW after the descent of the gas supply unit 730 is completed.

In the state shown in FIG. 7, the UV light 50 passes through the light-transmitting member 712 and the first resin layer 32a (see FIG. 2) forming the adhesive tape 32, and is irradiated onto the second resin layer 32b (see FIG. 2) forming the adhesive layer of the adhesive tape 32. As a result, the second resin layer 32b, composed of the UV-curable resin, hardens, and the adhesive strength of the adhesive layer decreases. In this case, the UV light irradiation unit 700 of the present embodiment maintains the surface of the adhesive tape 32 in an inert atmosphere, oxygen inhibition does not occur, and the adhesive strength of the exposed surface of the adhesive tape 32 (the part where the semiconductor chip 33 is not adhered) can be sufficiently reduced.

When the adhesive strength of the adhesive tape 32 is sufficiently reduced, the semiconductor chip 33 is put into a state where it can be easily peeled off from the adhesive tape 32. Therefore, when irradiating the UV light 50 onto the adhesive tape 32, it is desirable to weaken the flow speed of the inert gas 40 discharged from the gas discharge portion 732 so that the semiconductor chip 33 is not peeled off due to contact with the inert gas 40. That is, it is preferable to control the flow rate and flow speed of the inert gas 40 so that the inert gas 40 is gently discharged from the gas discharge portion 732.

As described above, when irradiating UV light onto the back surface (the second surface 32R) of the adhesive tape 32, the UV light irradiation unit 700 of the present embodiment maintains the atmosphere in contact with the surface (the first surface 32F) of the adhesive tape 32 in an inert atmosphere, so that the adhesive strength of the adhesive tape 32 can be reduced without causing oxygen inhibition. That is, according to the present embodiment, when irradiating the UV light 50 onto the resin film (the adhesive tape 32) to which the electronic component (the semiconductor chip 33) is adhered to reduce the adhesive strength, the influence of oxygen inhibition can be suppressed.

As described above, according to the present embodiment, since the influence of oxygen inhibition can be effectively suppressed, damage to the semiconductor chip 33 due to insufficient reduction in adhesive strength can be prevented when performing a pickup process (process of removing the semiconductor chip 33 individually from the adhesive tape 32) in the bonding apparatus 20. For example, in the case where the semiconductor chip 33 is a thin semiconductor chip of the order of several tens of microns, such as a memory, there is a concern about damage during the pickup process. However, by using the UV light irradiation unit 700 of the present embodiment, the adhesive strength of the adhesive tape 32 can be sufficiently reduced, preventing damage or chipping when peeling the semiconductor chip 33 from the adhesive tape 32. In addition, by preventing the oxygen inhibition described above and sufficiently curing the adhesive layer of the adhesive tape 32, it is possible to prevent residues of the adhesive layer from adhering to the semiconductor chip 33 when peeling the semiconductor chip 33 from the adhesive tape 32. As described above, according to the present embodiment, not only can the semiconductor chip 33 be peeled off from the adhesive tape 32 while preventing damage or chipping, but it can also prevent residues of the adhesive layer from adhering to the peeled semiconductor chip 33.

Furthermore, in the present embodiment, although an example is shown in which the UV light irradiation unit 700 (the UV light irradiation apparatus) is arranged in the pretreatment apparatus 10 within the mounting system 1, which includes the pretreatment apparatus 10 and the bonding apparatus 20, the present disclosure is not limited to this example. For example, the UV light irradiation unit 700 may be arranged within the bonding apparatus 20, or may be included in the mounting system 1 as a standalone apparatus separate from the pretreatment apparatus 10 and the bonding apparatus 20.

### First Modification

In the present embodiment, although an example is shown in which the UV light 50 is irradiated onto the adhesive tape 32 of the supply substrate TW while the inert gas 40 is continuously supplied from the gas supply unit 730, the present disclosure is not limited to this example. For example, after the descent of the gas supply unit 730 is completed, the supply of the inert gas 40 may be stopped, and then the UV light 50 may be irradiated onto the adhesive tape 32 of the supply substrate TW. In the state shown in FIG. 6, the space between the adhesive tape 32 and the gas discharge portion 732 is sufficiently narrow and sufficiently filled with the inert gas 40. Therefore, even after stopping the supply of the inert gas 40, the space between the adhesive tape 32 and the gas discharge portion 732 can be maintained in an inert atmosphere for a while. Therefore, while the inert atmosphere is maintained, even if the UV light 50 is irradiated onto the adhesive tape 32, the adhesive strength of the adhesive tape 32 can be reduced without being affected by oxygen inhibition.

In the present embodiment, although an example is shown in which the gas supply unit 730 is configured to be movable in the up-down direction, the present disclosure is not limited to this example, and the support stage 710 may be configured to move in the up-down direction. That is, the gas supply unit 730 and the support stage 710 may be movable relative to each other in directions approaching and away from each other. In the case where the support stage 710 is moved in the up-down direction, it is preferable to also move the light source unit 720 in the up-down direction. This is because if an optical path distance between the light-transmitting member 712 of the support stage 710 and the light source 721 of the light source unit 720 changes, an optical path distance between the adhesive tape 32 and the light source 721 will change, which may result in a change in the intensity of the UV light 50 irradiated onto the adhesive tape 32.

### Third Modification

For the gas supply unit 730 of the present embodiment, although the configuration is shown in which the plurality of openings 732a is provided in the gas discharge portion 732, and the inert gas 40 is discharged from the plurality of openings 732a, the present disclosure is not limited to this example. For example, a porous member (for example, porous ceramic) may be arranged inside the head portion 731, and the inert gas 40 may be discharged through a plurality of pores in the porous member.

By configuring the inert gas 40 to be discharged through the plurality of pores, the flow of the inert gas can be dispersed, and the flow speed of the inert gas can be suppressed. This prevents the semiconductor chip 33 from peeling off due to the wind pressure of the inert gas 40 when the adhesive strength of the adhesive tape 32 is reduced. In addition, since the flow of the inert gas is dispersed, the injection of the inert gas 40 from the plurality of pores becomes uniform, reducing the bias in the flow rate of the inert gas 40 injected from each pore. In other words, when the inert gas 40 is discharged through the plurality of pores in the porous member, the inert gas 40 can be injected more widely and uniformly, which has an advantage that the effect of suppressing oxygen inhibition does not vary within the plane of the supply substrate TW.

In the present embodiment, although an example is shown in which the gas supply unit 730 moves in the up-down direction, the gas supply unit 730 may also rotate around an axis in the vertical direction. That is, the gas discharge portion 732 may be configured to discharge the inert gas 40 while rotating. By discharging the inert gas 40 towards the supply substrate TW while rotating the gas discharge portion 732, a flow in the rotational direction occurs in the inert gas 40, thereby efficiently expelling air (especially oxygen gas) from the space between the gas discharge portion 732 and the first surface 32F of the adhesive tape 32.

Furthermore, instead of or in combination with the configuration in which the gas supply unit 730 rotates, the support stage 710 may be rotated around an axis in the vertical direction. In this case, the light source unit 720 may be rotated along with the support stage 710. Even in this case, a flow in the rotational direction occurs in the inert gas 40, thereby efficiently expelling air (especially oxygen gas) from the space between the gas discharge portion 732 and the first surface 32F of the adhesive tape 32.

### Second Embodiment

In the present embodiment, an example in which the configuration of the gas supply unit is different from that of the first embodiment will be described. Specifically, a UV light irradiation unit 700A of the present embodiment has a configuration in which a sidewall 734 is arranged in the gas supply unit 730, and the sides of the space between the gas discharge portion 732 and the adhesive tape 32 are surrounded by protective walls. The basic configuration of the UV light irradiation unit 700A in the present embodiment is the same as that of the UV light irradiation unit 700 in the first embodiment. Therefore, in the present embodiment, the explanation will focus on the parts of the configuration that are different from those in the first embodiment. For the same configuration as the UV light irradiation unit 700 of the first embodiment, redundant explanations may be omitted by using the same reference signs.

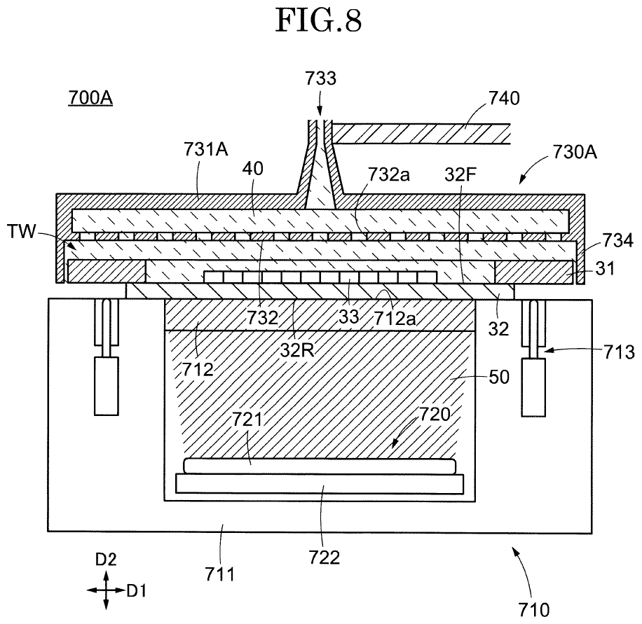

FIG. 8 is a diagram showing a state in which the UV light 50 is irradiated from the light source unit 720 in the UV light irradiation unit 700A according to an embodiment of the present disclosure. The UV light irradiation unit 700A of the present embodiment includes a gas supply unit 730A. The sidewall 734 protruding downward is provided on the sides of a head portion 731A of the gas supply unit 730A. Although not shown, the gas discharge portion 732 has a substantially circular shape in a plan view. Therefore, the sidewall 734 is provided in an annular shape to surround the gas discharge portion 732. It is desirable to make a distance between the sidewall 734 and the sides of the frame 31 of the supply substrate TW as narrow as possible.

In addition, to continuously fill the space between the gas discharge portion 732 and the adhesive tape 32 with the inert gas 40, it is desirable to provide a discharge port so that the inert gas 40 can be discharged from the space between the gas discharge portion 732 and the adhesive tape 32 even after the gas supply unit 730A has moved to the processing position, as shown in FIG. 8. For example, a gap between the sidewall 734 described above and the sides of the frame 31 of the supply substrate TW can be used as a discharge port for the inert gas 40. In addition, a through hole for discharging the inert gas 40 may be provided in the sidewall 734.

Furthermore, during the process of moving the gas supply unit 730A from the standby position to the processing position, it is desirable to fill the space surrounded by the gas discharge portion 732 and the sidewall 734 with the inert gas 40. For example, when moving the gas supply unit 730A from the standby position to the processing position, the inert gas 40 continues to be discharged from the gas discharge portion 732. In this case, the gas supply unit 730A descends while expelling the air in the space surrounded by the gas discharge portion 732 and the sidewall 734 downward and sideways with the inert gas 40, so that the space described above can be quickly replaced with the inert gas 40. As a result, during the process of moving the gas supply unit 730A from the standby position to the processing position, the space surrounded by the gas discharge portion 732 and the sidewall 734 can be sufficiently filled with the inert gas 40.

In the present embodiment, since the sidewall 734 is provided to surround the sides of the space between the gas discharge portion 732 and the first surface 32F of the adhesive tape 32, it is possible to effectively suppress the inert gas 40 from flowing sideways. That is, according to the present embodiment, when the UV light 50 is irradiated onto the second surface 32R of the adhesive tape 32, the inert gas 40 can be retained in the space between the gas discharge portion 732 and the first surface 32F of the adhesive tape 32, and the atmosphere in the space can be continuously maintained in an inert atmosphere. In addition, according to the present embodiment, even if the supply of the inert gas 40 to the inside of the head portion 731A is stopped, it is possible to maintain the space described above in an inert atmosphere, thereby reducing the consumption of the inert gas 40.

### Third Embodiment

In the present embodiment, an example in which the configuration of the support stage is different from that of the first embodiment will be described. Specifically, a UV light irradiation unit 700B of the present embodiment has a configuration in which a barrier unit 714 is arranged on the support stage 710, and the sides of the space between the gas discharge portion 732 and the adhesive tape 32 are surrounded by the protective walls. The basic configuration of a support stage 710B in the present embodiment is similar to that of the support stage 710 in the first embodiment. Therefore, in the present embodiment, the explanation will focus on the parts of the configuration that are different from those in the first embodiment. For the same configuration as the support stage 710 of the first embodiment, redundant explanations may be omitted by using the same reference signs.

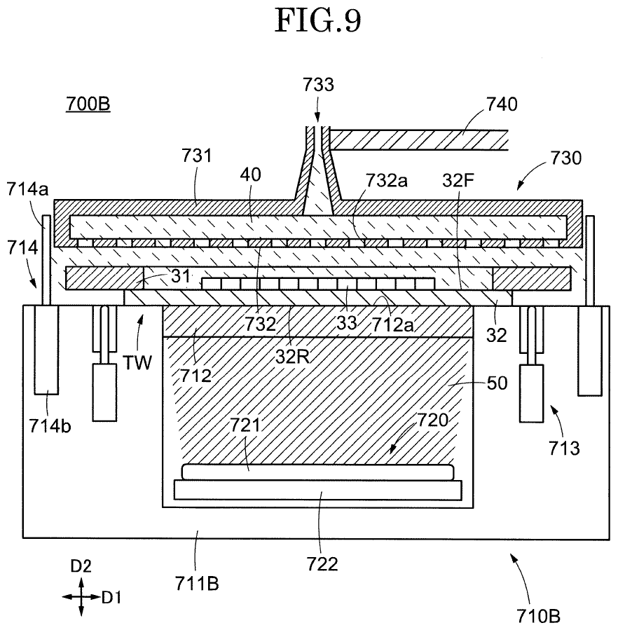

FIG. 9 is a diagram showing a state in which the UV light 50 is irradiated from the light source unit 720 in the UV light irradiation unit 700B according to an embodiment of the present disclosure. The support stage 710B of the present embodiment includes the barrier unit 714 arranged in a housing 711B. The barrier unit 714 includes a lifting wall 714a that moves up and down to surround the sides of the space between the gas discharge portion 732 and the first surface 32F of the adhesive tape 32, and a lifting wall drive unit 714b that moves the lifting wall 714a in the up-down direction. Although not shown, the head portion 731 of the gas supply unit 730 has a substantially circular shape in a plan view. Therefore, the lifting wall 714a is arranged in an annular shape to surround the head portion 731. It is desirable to make a distance between the lifting wall 714a and the sides of the head portion 731 as narrow as possible.

In addition, to continuously fill the space between the gas discharge portion 732 and the adhesive tape 32 with the inert gas 40, it is desirable to provide a discharge port so that the inert gas 40 can be discharged from the space between the gas discharge portion 732 and the adhesive tape 32 even after the gas supply unit 730 has moved to the processing position, as shown in FIG. 9. For example, a gap between the lifting wall 714a described above and the sides of the head portion 731 can be used as a discharge port for the inert gas 40. In addition, a through hole for discharging the inert gas 40 may be provided in the lifting wall 714a.

Furthermore, when moving the gas supply unit 730 from the standby position to the processing position, it is preferable to continue discharging the inert gas 40 from the gas discharge portion 732. In this case, the gas supply unit 730 descends while expelling the air below the gas discharge portion 732 sideways with the inert gas 40, so that when the gas supply unit 730 reaches the processing position, the space between the gas discharge portion 732 and the adhesive tape 32 can be filled with the inert gas 40. Thereafter, the lifting wall 714a is raised to surround the sides of the space described above, and the space between the gas discharge portion 732 and the adhesive tape 32 can be filled with the inert gas 40.

In the present embodiment, since the lifting wall 714a is provided to surround the sides of the space between the gas discharge portion 732 and the first surface 32F of the adhesive tape 32, it is possible to effectively suppress the inert gas 40 from flowing sideways. That is, according to the present embodiment, when the UV light 50 is irradiated onto the second surface 32R of the adhesive tape 32, the inert gas 40 can be retained in the space between the gas discharge portion 732 and the first surface 32F of the adhesive tape 32, and the atmosphere in the space can be continuously maintained in an inert atmosphere. In addition, according to the present embodiment, even if the supply of the inert gas 40 to the inside of the head portion 731 is stopped, it is possible to maintain the space described above in an inert atmosphere, thereby reducing the consumption of the inert gas 40.

In the example shown in FIG. 9, although the configuration is shown in which the lifting wall 714a is arranged to surround the head portion 731, the present disclosure is not limited to this example. For example, it is also possible to arrange the lifting wall 714a close to the vicinity of the side of the frame 31 of the supply substrate TW. In this case, the upper end of the lifting wall 714a may be configured to contact the head portion 731, or may be configured not to contact the head portion 731. For example, when it is detected that the upper end of the lifting wall 714a has contacted the head portion 731, the lifting wall drive unit 714b may be controlled to stop the ascent of the lifting wall 714a. In this case, it becomes possible to maintain the space between the gas discharge portion 732 and the first surface 32F of the adhesive tape 32 in an inert atmosphere more efficiently.

### Fourth Embodiment

In the present embodiment, a UV light irradiation unit having a configuration that combines the second and third embodiments will be described. Specifically, a UV light irradiation unit 700C of the present embodiment includes the gas supply unit 730A described in the second embodiment and the support stage 710B described in the third embodiment. That is, the UV light irradiation unit 700C of the present embodiment has a configuration in which the sidewall 734 is provided in the gas supply unit 730A, and the barrier unit 714 is provided in the support stage 710, thereby surrounding the sides of the space between the gas discharge portion 732 and the adhesive tape 32 by double protective walls. The basic configuration of the UV light irradiation unit 700C in the present embodiment is similar to that of the UV light irradiation unit 700 in the first embodiment. In addition, the configuration of the gas supply unit 730A is as described in the second embodiment, and the configuration of the support stage 710B is as described in the third embodiment, so for the same configuration as each embodiment, redundant explanations may be omitted by using the same reference signs.

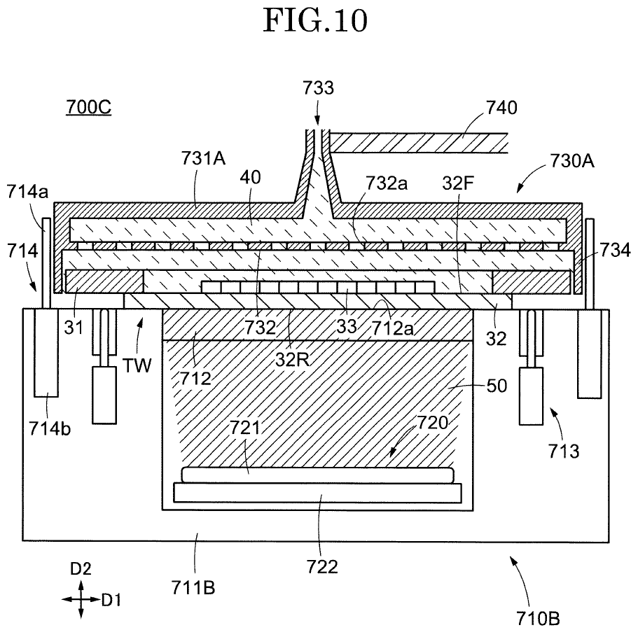

FIG. 10 is a diagram showing a state in which the UV light 50 is irradiated from the light source unit 720 in the UV light irradiation unit 700C according to an embodiment of the present disclosure. The UV light irradiation unit 700C is provided with the sidewall 734 in the gas supply unit 730A, and the barrier unit 714 (specifically, the lifting wall 714a) is arranged in the support stage 710B. Therefore, the sides of the space between the gas discharge portion 732 and the first surface 32F of the adhesive tape 32 can be surrounded by double protective walls. In this case, a so-called labyrinth structure can be formed on the sides of the space described above, and the inert gas 40 can be more effectively maintained inside the head portion 731A.

In addition, similar to the second and third embodiments, to continuously fill the space with the inert gas 40, it is desirable to provide a discharge port so that the inert gas 40 can be discharged from the space between the gas discharge portion 732 and the adhesive tape 32. For example, the gap between the side wall 734 and the side of the frame 31 of the supply substrate TW, and a gap between the head portion 731A and the lifting wall 714a can be used as a discharge port for the inert gas 40. In addition, a through hole for discharging the inert gas 40 may be provided in the side wall 734 and/or the lifting wall 714a.

Furthermore, similar to the second embodiment, it is desirable to fill the space surrounded by the gas discharge portion 732 and the side wall 734 with the inert gas 40 during the process of moving the gas supply unit 730A from the standby position to the processing position. For example, when moving the gas supply unit 730A from the standby position to the processing position, the space described above can be quickly replaced with the inert gas 40 by continuously discharging the inert gas 40 from the gas discharge portion 732. In this case, when the gas supply unit 730 reaches the processing position, the space between the gas discharge portion 732 and the adhesive tape 32 is filled with the inert gas 40, so by raising the lifting wall 714a, the space between the gas discharge portion 732 and the adhesive tape 32 can be closed while remaining filled with the inert gas 40.

According to the present embodiment, when the UV light 50 is irradiated onto the second surface 32R of the adhesive tape 32, the inert gas 40 can be retained in the space between the gas discharge portion 732 and the first surface 32F of the adhesive tape 32, and the atmosphere in the space can be continuously maintained in an inert atmosphere. In addition, according to the present embodiment, even if the supply of the inert gas 40 to the inside of the head portion 731 is stopped, it is possible to maintain the space described above in an inert atmosphere, thereby reducing the consumption of the inert gas 40.

### Fifth Embodiment

In the present embodiment, an example in which the configuration of the gas supply unit is different from that of the first embodiment will be described. Specifically, a UV light irradiation unit 700D of the present embodiment has a configuration in which a sealing member 735, which will be described later, is arranged between a gas supply unit 730D and the frame 31 of the supply substrate TW, thereby forming a sealed space between a gas discharge portion 732D and the adhesive tape 32. The basic configuration of the UV light irradiation unit 700D of the present embodiment is similar to that of the UV light irradiation unit 700 of the first embodiment. Therefore, in the present embodiment, the explanation will focus on the parts where the configuration differs from those in the first embodiment. For the same configuration as the UV light irradiation unit 700 of the first embodiment, redundant explanations may be omitted by using the same reference signs.

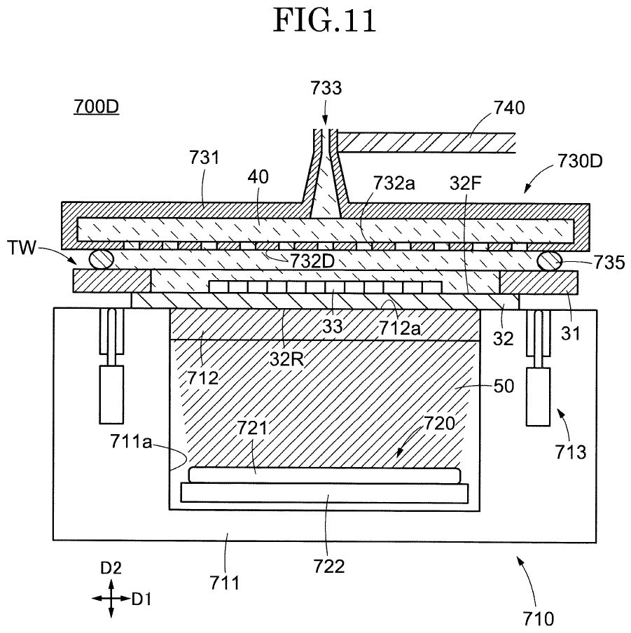

FIG. 11 is a diagram showing a state in which the UV light 50 is irradiated from the light source unit 720 in the UV light irradiation unit 700D according to an embodiment of the present disclosure. The UV light irradiation unit 700D of the present embodiment includes the gas supply unit 730D. The gas supply unit 730D has the sealing member 735 arranged to face the support stage 710 to surround the gas discharge portion 732D. Specifically, in the example shown in FIG. 11, the sealing member 735 is provided near the outer edge of the gas discharge portion 732D to face the frame 31 of the supply substrate TW.

Although not shown, since the gas discharge portion 732D has a substantially circular shape in a plan view, the sealing member 735 is provided in an annular shape to surround the gas discharge portion 732. Therefore, by lowering the gas supply unit 730D and bringing the sealing member 735 into contact with the frame 31 of the supply substrate TW, a space between the gas discharge portion 732D and the first surface 32F of the adhesive tape 32 can be made into a sealed space.

In the present embodiment as well, similar to the third embodiment, it is preferable to continue discharging the inert gas 40 from the gas discharge portion 732D during the process of moving the gas supply unit 730D from the standby position to the processing position. In this case, the gas supply unit 730D descends while expelling the air below the gas discharge portion 732D sideways with the inert gas 40, so when a sealed space is formed between the gas discharge portion 732D and the adhesive tape 32 (i.e., when the sealing member 735 is brought into contact with the frame 31 of the supply substrate TW), the sealed space can be filled with the inert gas 40.

In the present embodiment, since the space between the gas discharge portion 732 and the first surface 32F of the adhesive tape 32 can be made into a sealed space, it is possible to prevent the inert gas 40 from flowing sideways. That is, according to the present embodiment, when the UV light 50 is irradiated onto the second surface 32R of the adhesive tape 32, the inert gas 40 can be retained in the space between the gas discharge portion 732 and the first surface 32F of the adhesive tape 32, and the atmosphere in the space can be continuously maintained in an inert atmosphere. In addition, according to the present embodiment, even if the supply of the inert gas 40 to the inside of the head portion 731 is stopped, it is possible to maintain the space described above in an inert atmosphere, thereby reducing the consumption of the inert gas 40.

### Sixth Embodiment

In the present embodiment, an example in which the configuration of the support stage is different from that of the first embodiment will be described. Specifically, in the present embodiment, while expanding the adhesive tape 32 of the supply substrate TW, the inert gas 40 is supplied to the first surface 32F, and UV light is irradiated onto the second surface 32R. For example, as one example, a light-transmitting member 712E, which will be described later, is pressed against the adhesive tape 32 of the supply substrate TW from the second surface 32R side, thereby expanding the adhesive tape 32. In addition, as another example, the frame 31 of the supply substrate TW is pressed down below the semiconductor chip 33 to expand the adhesive tape 32. In the present embodiment, the explanation will focus on the parts of the configuration that are different from those in the first embodiment, and for the same configuration as the UV light irradiation unit 700 of the first embodiment, redundant explanations may be omitted by using the same reference signs.

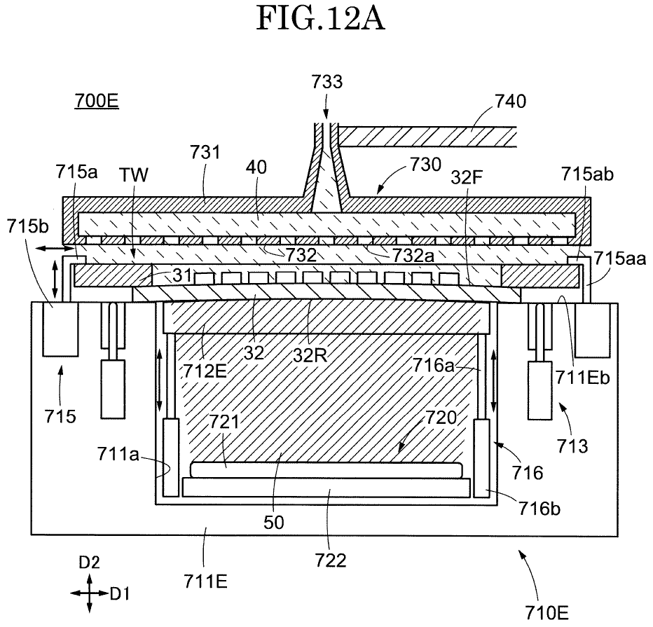

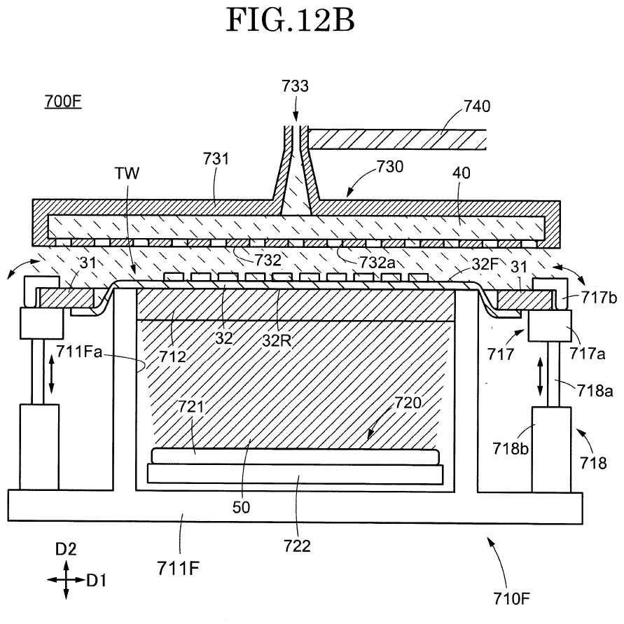

FIG. 12A is a diagram showing a state in which the UV light 50 is irradiated from the light source unit 720 in a UV light irradiation unit 700E according to an embodiment of the present disclosure. A support stage 710E of the present embodiment includes a fixing mechanism 715 and a lifting mechanism 716.

The fixing mechanism 715 includes a fixing arm 715a and an arm drive unit 715b. The fixing arm 715a has a function of pressing the frame 31 of the supply substrate TW from above to fix the supply substrate TW. Specifically, the fixing arm 715a has a first portion 715aa extending in the up-down direction (vertical direction, direction D2) and a second portion 715ab extending in the left-right direction (direction D1) continuous with the first portion 715aa, and fixes the supply substrate TW by pressing the frame 31 downward using the second portion 715ab. For this purpose, as indicated by the arrows in FIG. 12A, the fixing arm 715a is movable in the up-down direction and the left-right direction by the operation of the arm drive unit 715b. Although not shown, four fixing mechanisms 715 are arranged around the opening 711a at positions point-symmetrical to the center of the opening 711a. That is, in the present embodiment, the plurality of fixing mechanisms 715 is evenly arranged in the circumferential direction of the frame 31 of the supply substrate TW. However, the arrangement of the fixing mechanism 715 is not limited to this example, and the fixing mechanism 715 may be arranged in any manner as long as the outer periphery of the supply substrate TW can be evenly pressed.

The lifting mechanism 716 includes a lifting arm 716a and an arm drive unit 716b. The lifting mechanism 716 has a function of moving the light-transmitting member 712E in the up-down direction (vertical direction, direction D2). Specifically, the lifting arm 716a of the lifting mechanism 716 is positioned below the light-transmitting member 712E, and can push the light-transmitting member 712E upward by moving the lifting arm 716a upward. Conversely, the lifting mechanism 716 can move the light-transmitting member 712E downward by moving the lifting arm 716a downward. The lifting arm 716a and the light-transmitting member 712E may or may not be connected.

Although not shown, four lifting mechanisms 716 are arranged inside the opening 711a at positions point-symmetrical to the center of the opening 711a. As a result, the lifting mechanism 716 can move the light-transmitting member 712E in the up-down direction with equal force. However, the arrangement of the lifting mechanism 716 is not limited to this example, and the lifting mechanism 716 can be arranged in any manner as long as the outer periphery of the light-transmitting member 712E can be evenly pushed up.

Here, an operation of the UV light irradiation unit 700E of the present embodiment will be described. First, in the initial state, the gas supply unit 730 is in the standby position, and the fixing arm 715a is in a state where the first portion 715aa is moved outward at a raised position. That is, the fixing arm 715a is retracted to a position where it does not interfere when the supply substrate TW is loaded in.

Next, the supply substrate TW is loaded into the UV light irradiation unit 700E and placed on the support stage 710E by the push-pull mechanism 713. When the supply substrate TW is placed on the support stage 710E, the fixing arm 715a moves horizontally inward. Thereafter, the fixing arm 715a moves the first portion 715aa downward to contact the frame 31. As a result, the fixing arm 715a can press the frame 31 from above and fix the upward movement.

Next, the arm drive unit 716b of the lifting mechanism 716 is driven to move the lifting arm 716a upward. When the lifting arm 716a moves upward, the light-transmitting member 712E also moves upward, so the adhesive tape 32 is pushed out from the back surface side to the light-transmitting member 712E. As a result, the adhesive tape 32 is expanded, and each semiconductor chip 33 adhered to the adhesive tape 32 is spaced apart from the others.

Next, the gas supply unit 730 is lowered to the processing position, and the gas discharge portion 732 is brought close to the first surface 32F of the adhesive tape 32. In this case, since each semiconductor chip 33 is spaced apart from the others as described above, the gaps between the semiconductor chips are filled with the inert gas 40. In this state, UV light is irradiated from the light source unit 720 onto the second surface 32R of the adhesive tape 32.

When the UV light irradiation is completed, the supply substrate TW is unloaded from the UV light irradiation unit 700E. When unloading the supply substrate TW, the reverse operation of the loading procedure described above is performed, the fixing arm 715a is retracted outward, and then the supply substrate TW is unloaded.

In the example shown in FIG. 12A, the supply substrate TW is fixed by the fixing mechanism 715, and the light-transmitting member 712E is pushed up by the lifting mechanism 716, thereby expanding the adhesive tape 32 of the supply substrate TW. In other words, by pushing up the adhesive tape 32 of the supply substrate TW from the back surface (the second surface 32R), as shown in FIG. 12, the adhesive tape 32 extends radially from the center, and the gaps between the semiconductor chips 33 can be widened. By widening the gaps between the semiconductor chips 33, the atmosphere in the gap portions can be made sufficiently inert, thereby suppressing oxygen inhibition around each semiconductor chip 33. This reduces the problem of oxygen inhibition occurring in the gap portions between the semiconductor chips 33.

In the example shown in FIG. 12A, the upper surface of the light-transmitting member 712E (i.e., the portion in contact with the second surface 32R of the adhesive tape 32) is a curved surface. Since the upper surface of the light-transmitting member 712E is curved, the surface (the first surface 32F) of the adhesive tape 32 is also curved and expanded, and the gaps between the semiconductor chips 33 can be widened evenly. However, the present disclosure is not limited to this example, and the upper surface of the light-transmitting member 712E may be a flat surface.

Furthermore, in the example shown in FIG. 12A, the light-transmitting member 712E is configured to be movable in the up-down direction, but if the upper surface of the light-transmitting member 712E is a curved surface, the lifting mechanism 716 may be omitted. Specifically, the light-transmitting member 712 is arranged so that the curved surface of the light-transmitting member 712E is positioned above the upper surface 711Eb of a housing 711E of the support stage 710E. With such a configuration, it is possible to expand the adhesive tape 32 along the curved surface when the supply substrate TW is fixed by the fixing mechanism 715 (i.e., when the frame 31 of the supply substrate TW is pressed from above).

Next, FIG. 12B is a diagram showing a state in which the UV light 50 is irradiated from the light source unit 720 in a UV light irradiation unit 700F according to an embodiment of the present disclosure. A support stage 710F of the present embodiment includes a housing 711F, the light-transmitting member 712, a frame holding mechanism 717, and a lifting mechanism 718.

The housing 711F is a member that serves as the base of the support stage 710F and functions as a pedestal that supports most of the supply substrate TW (specifically, excluding the frame 31). The light-transmitting member 712 that transmits UV light is arranged inside the opening 711Fa of the housing 711F to face the gas discharge portion 732 of the gas supply unit 730. In addition, the light source unit 720 is arranged below the light-transmitting member 712. Furthermore, in the example shown in FIG. 12B, the light-transmitting member 712 is fitted inside near the upper end of the opening 711Fa, but the present disclosure is not limited to this example, and the light-transmitting member 712 may be omitted.

The frame holding mechanism 717 has the function of holding the frame 31 of the supply substrate TW and includes a support portion 717a and a clamp 717b. The support portion 717a is where the frame 31 of the loaded supply substrate TW is placed. In addition, the clamp 717b is provided on an upper surface of the support portion 717a. As indicated by the arrows, the clamp 717b is rotatable about the connecting portion with the support portion 717a. When the supply substrate TW is loaded, the clamp 717b is in a state of being rotated outward. When the supply substrate TW is loaded, the clamp 717b rotates inward and cooperates with the support portion 717a to clamp and hold the frame 31. Although not shown, four frame holding mechanisms 717 are arranged around the opening 711Fa at positions point-symmetrical to the center of the opening 711Fa. That is, in the present embodiment, the plurality of frame holding mechanisms 717 is evenly arranged in the circumferential direction of the frame 31 of the supply substrate TW. However, the arrangement of the frame holding mechanism 717 is not limited to this example, and the frame holding mechanism 717 may be arranged in any manner as long as the outer periphery of the supply substrate TW can be evenly pressed.

The lifting mechanism 718 has a function of moving the frame holding mechanism 717 in the up-down direction (vertical direction) and includes a rod 718a and a rod drive portion 718b. The rod 718a has the support portion 717a of the frame holding mechanism 717 fixed at its upper end and is connected to the rod drive portion 718b at its lower end. The rod drive portion 718b is an actuator that has a function of moving the rod 718a in the up-down direction. For example, an electric cylinder, an air cylinder, etc., can be used as the rod drive portion 718b. When the rod 718a performs a lifting operation due to the operation of the rod drive portion 718b, the frame holding mechanism 717 also moves up and down.

Here, an operation of the UV light irradiation unit 700F of the present embodiment will be described. First, in the initial state, the gas supply unit 730 is in the standby position, and the frame holding mechanism 717 is in a state of being moved upward. Specifically, the upper surface of the support portion 717a of the frame holding mechanism 717 has moved to the same height as the upper surface of the light-transmitting member 712. In addition, as described above, the clamp 717b of the frame holding mechanism 717 is in a state of being rotated outward. That is, the clamp 717b is retracted to a position where it does not interfere when the supply substrate TW is loaded in.

Next, the supply substrate TW is loaded into the UV light irradiation unit 700F and placed on the support stage 710F. In this case, the frame 31 of the supply substrate TW is placed on the support portion 717a, and most of the adhesive tape 32 is placed on the light-transmitting member 712. When the supply substrate TW is placed on the support stage 710F, the clamp 717b is rotated inward to clamp the frame 31 with the support portion 717a and the clamp 717b.

After the loading of the supply substrate TW and the holding of the frame 31 are completed, the rod drive portion 718b of the lifting mechanism 718 is driven to move the rod 718a downward. When the rod 718a moves downward, the frame holding mechanism 717 also moves downward, so that the adhesive tape 32 is stretched outward. As a result, the adhesive tape 32 is expanded, and each semiconductor chip 33 adhered to the adhesive tape 32 is spaced apart from the others.

Next, the gas supply unit 730 is lowered to the processing position, and the gas discharge portion 732 is brought close to the first surface 32F of the adhesive tape 32. In this case, since each semiconductor chip 33 is spaced apart from the others as described above, the gaps between the semiconductor chips are filled with the inert gas 40. In this state, UV light is irradiated from the light source unit 720 onto the second surface 32R of the adhesive tape 32.

When the UV light irradiation is completed, the supply substrate TW is unloaded from the UV light irradiation unit 700F. When unloading the supply substrate TW, the reverse operation of the loading procedure described above is performed. That is, the frame holding mechanism 717 is raised to return to the initial position, the clamp 717b is rotated outward, and then the supply substrate TW is unloaded.

In the example shown in FIG. 12B, the adhesive tape 32 of the supply substrate TW is stretched and can be expanded by lowering the frame holding mechanism 717 with the lifting mechanism 718 while holding the frame 31 of the supply substrate TW with the frame holding mechanism 717. As a result, as shown in FIG. 12B, the gaps between the semiconductor chips 33 can be widened, and the atmosphere in the gap portions can be made sufficiently inert. Therefore, it is possible to suppress oxygen inhibition around each semiconductor chip 33 and to suppress oxygen inhibition in the gap portions between the semiconductor chips 33.

### Seventh Embodiment

In the present embodiment, an example in which the configuration of the gas supply unit is different from that of the first embodiment will be described. Specifically, in a UV light irradiation unit 700G of the present embodiment, a gas supply unit 730G is provided with a plurality of supply ports 733Ga to 733Ge, and is configured to uniformly supply the inert gas 40 inside a head portion 731G. The basic configuration of the UV light irradiation unit 700G of the present embodiment is similar to that of the UV light irradiation unit 700 of the first embodiment. Therefore, in the present embodiment, the explanation will focus on the parts of the configuration that are different from those in the first embodiment. For the same configuration as the UV light irradiation unit 700 of the first embodiment, redundant explanations may be omitted by using the same reference signs.

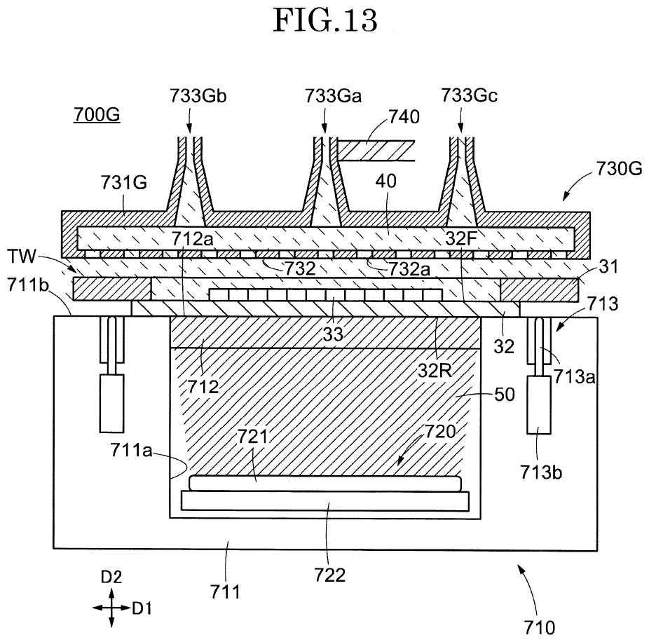

FIG. 13 is a diagram showing a state in which the UV light 50 is irradiated from the light source unit 720 in the UV light irradiation unit 700G according to an embodiment of the present disclosure. FIG. 14 is a plan view showing a configuration of the gas supply unit 730G in the UV light irradiation unit 700G according to an embodiment of the present disclosure. The UV light irradiation unit 700G of the present embodiment includes the gas supply unit 730G. The head portion 731G of the gas supply unit 730G is provided with the plurality of supply ports 733Ga to 733Ge. In the example shown in FIG. 13, three supply ports 733Ga to 733Gc arranged in the horizontal direction are shown, but as shown in FIG. 14, in the present embodiment, a total of five supply ports 733Ga to 733Ge are provided in a cross shape. In the present embodiment, it is preferable to arrange the supply ports 733Ga to 733Ge at positions point-symmetrical to the center of the gas discharge portion 732 in a plan view. By arranging the supply ports 733Ga to 733Ge in this manner, it is possible to uniformly supply the inert gas 40 inside the head portion 731G. However, there are no particular limitations on the positions and number of the supply ports 733Ga to 733Ge.

In the present embodiment, since the plurality of supply ports 733Ga to 733Ge for supplying the inert gas 40 is arranged in the head portion 731G, the supply of the inert gas 40 can be dispersed inside the head portion 731G without being concentrated in one place. This makes it possible to suppress the flow of the inert gas 40 inside the head portion 731G, and as a result, it is possible to suppress the flow speed of the gas discharged from the plurality of openings 732a. That is, when the UV light 50 is irradiated onto the adhesive tape 32, the flow speed of the inert gas 40 discharged from the gas discharge portion 732 can be weakened, thereby suppressing the peeling of the semiconductor chip 33 due to the inert gas 40 hitting the semiconductor chip 33. In addition, by dispersing the inert gas 40 inside the head portion 731G, it becomes possible to discharge the inert gas 40 uniformly, resulting in the advantage of a uniform distribution of the inert gas 40 discharge.

### Eighth Embodiment

In the present embodiment, an example in which the configuration of the gas supply unit is different from that of the first embodiment will be described. Specifically, a gas supply unit 730H of the present embodiment has a configuration in which the plurality of openings provided in the gas discharge portion 732H has different hole diameters or different arrangement densities near the center and near the outer edge of the gas discharge portion 732H. The basic configuration of the gas supply unit in the present embodiment is similar to that of the gas supply unit 730 in the first embodiment. Therefore, in the present embodiment, the explanation will focus on the parts of the configuration that are different from those in the first embodiment. For the same configuration as the gas supply unit 730 of the first embodiment, redundant explanations may be omitted by using the same reference signs.

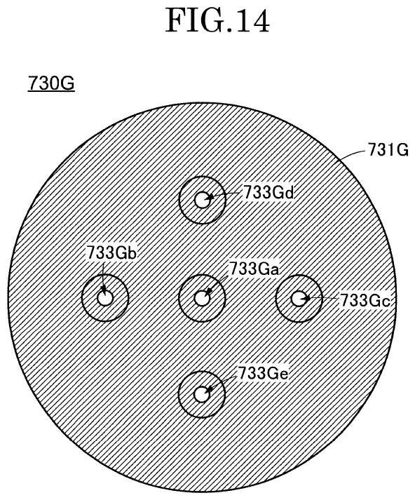

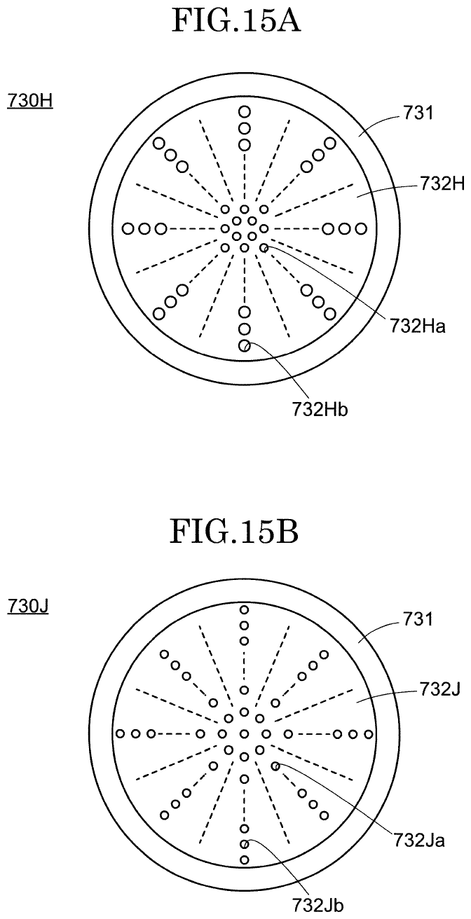

FIG. 15A is a diagram schematically showing a configuration of the gas discharge portion 732H in the gas supply unit 730G according to an embodiment of the present disclosure. However, in the example shown in FIG. 15A, some of the openings are omitted and indicated by dotted lines. The gas discharge portion 732H of the gas supply unit 730H shown in FIG. 15A is provided with a plurality of openings 732Ha and 732Hb. The plurality of openings 732Ha is positioned near the center of the gas discharge portion 732H, and the plurality of openings 732Hb is positioned near the outer edge of the gas discharge portion 732H. In this case, the hole diameters of the openings 732Ha and 732Hb are different from each other. Specifically, the diameter of the opening 732Ha is smaller than the diameter of the opening 732Hb. This allows the inert gas discharged from the gas discharge portion 732H to have a low flow rate near the center and a high flow rate near the outer edge, preventing the inert gas from concentrating near the center. Therefore, the entire surface of the supply substrate TW can be uniformly covered with the inert gas.

In the example shown in FIG. 15A, only two types of openings having different diameters are illustrated, but the present disclosure is not limited to this example. For example, three or more types of openings having different diameters may be provided. In this case, three or more types of openings may be arranged so that the diameter of the openings increases from the inside to the outside.

FIG. 15B is a diagram schematically showing a configuration of a gas discharge portion 732J in a gas supply unit 730J according to an embodiment of the present disclosure. However, in the example shown in FIG. 15B, some of the openings are omitted and indicated by dotted lines. The gas discharge portion 732J of the gas supply unit 730J shown in FIG. 15B is provided with a plurality of openings 732Ja and 732Jb. The plurality of openings 732Ja is positioned near the center of the gas discharge portion 732J, and the plurality of openings 732Jb is positioned near the outer edge of the gas discharge portion 732J. In this case, the spacing between the openings 732Ja and the spacing between the openings 732Jb are different. Specifically, the spacing between the openings 732Ja is larger than the spacing between the openings 732Jb. In other words, the arrangement density of the plurality of openings 732Ja is smaller than the arrangement density of the plurality of openings 732Jb. This allows the inert gas discharged from the gas discharge portion 732J to have a low flow rate near the center and a high flow rate near the outer edge, preventing the inert gas from concentrating near the center. Therefore, the entire surface of the supply substrate TW can be uniformly covered with the inert gas.

In the example shown in FIG. 15B, only two types of openings having different arrangement densities are illustrated, but the present disclosure is not limited to this example. For example, three or more types of openings having different arrangement densities may be provided. In this case, three or more types of openings may be arranged so that the arrangement density of the plurality of openings increases from the inside to the outside.

### Ninth Embodiment

In the present embodiment, an example in which the configuration of the gas supply unit is different from that of the first embodiment will be described. Specifically, a gas supply unit 730K of the present embodiment has a configuration in which a plurality of openings provided in a gas discharge portion 732K has different hole diameters or different arrangement densities near the center and near the outer edge of the gas discharge portion 732K. The basic configuration of the gas supply unit in the present embodiment is similar to that of the gas supply unit 730 in the first embodiment. Therefore, in the present embodiment, the explanation will focus on the parts of the configuration that are different from those in the first embodiment. For the same configuration as the gas supply unit 730 of the first embodiment, redundant explanations may be omitted by using the same reference signs.

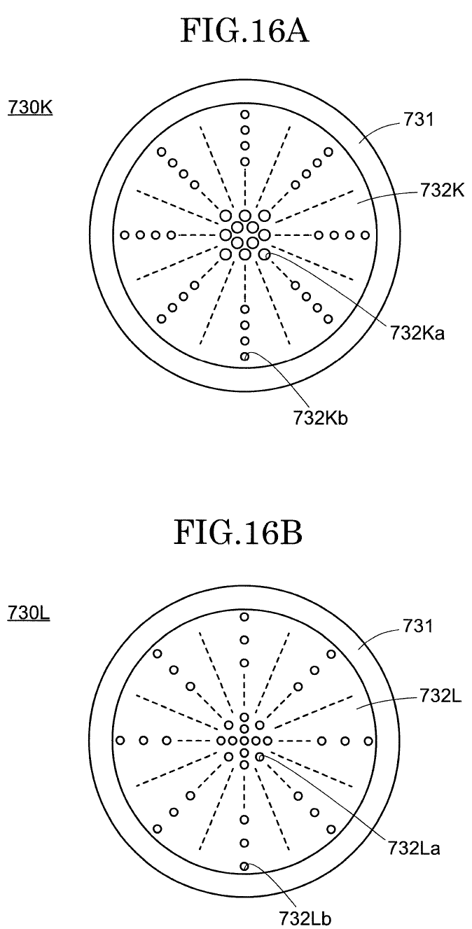

FIG. 16A is a diagram schematically showing a configuration of the gas discharge portion 732K in the gas supply unit 730J according to an embodiment of the present disclosure. However, in the example shown in FIG. 16A, some of the openings are omitted and indicated by dotted lines. The gas discharge portion 732K of the gas supply unit 730K shown in FIG. 16A is provided with a plurality of openings 732Ka and 732Kb. The plurality of openings 732Ka is positioned near the center of the gas discharge portion 732K, and the plurality of openings 732Kb is positioned near the outer edge of the gas discharge portion 732K. In this case, the hole diameters of the openings 732Ka and 732Kb are different from each other. Specifically, the diameter of the opening 732Ka is larger than the diameter of the opening 732Kb. This allows the inert gas discharged from the gas discharge portion 732K to have a high flow rate near the center and a low flow rate near the outer edge, so that the inert gas flows from the center to the outside. Therefore, the air remaining in the space between the gas discharge portion 732K and the adhesive tape 32 can be efficiently expelled sideways.

In the example shown in FIG. 16A, only two types of openings having different diameters are illustrated, but the present disclosure is not limited to this example. For example, three or more types of openings having different diameters may be provided. In this case, three or more types of openings may be arranged so that the diameter of the openings decreases from the inside to the outside.

FIG. 16B is a diagram schematically showing a configuration of a gas discharge portion 732L in a gas supply unit 730L according to an embodiment of the present disclosure. However, in the example shown in FIG. 16B, some of the openings are omitted and indicated by dotted lines. The gas discharge portion 732L of the gas supply unit 730L shown in FIG. 16B is provided with a plurality of openings 732La and 732Lb. The plurality of openings 732La is positioned near the center of the gas discharge portion 732L, and the plurality of openings 732Lb is positioned near the outer edge of the gas discharge portion 732L. In this case, the spacing between the openings 732La and the spacing between the openings 732Lb are different. Specifically, the spacing between the openings 732La is smaller than the spacing between the openings 732Lb. In other words, the arrangement density of the plurality of openings 732La is greater than the arrangement density of the plurality of openings 732Lb. This allows the inert gas discharged from the gas discharge portion 732L to have a high flow rate near the center and a low flow rate near the outer edge, so that the inert gas flows from the center to the outside. Therefore, the air remaining in the space between the gas discharge portion 732L and the adhesive tape 32 can be efficiently expelled sideways.

In the example shown in FIG. 16B, only two types of openings having different arrangement densities are illustrated, but the present disclosure is not limited to this example. For example, three or more types of openings having different arrangement densities may be provided. In this case, three or more types of openings may be arranged so that the arrangement density of the plurality of openings decreases from the inside to the outside.

### Tenth Embodiment

In the present embodiment, an example in which the configuration of the gas supply unit is different from that of the first embodiment will be described. Specifically, in a gas supply unit 730M of the present embodiment, a head portion 731M is configured with a slit nozzle, and moves horizontally above the adhesive tape 32 while injecting the inert gas 40. The basic configuration other than the gas supply unit in the present embodiment is similar to the UV light irradiation unit 700 in the first embodiment. Therefore, in the present embodiment, the explanation will focus on the parts of the configuration that are different from those in the first embodiment. For the same configuration as the UV light irradiation unit 700 of the first embodiment, redundant explanations may be omitted by using the same reference signs.

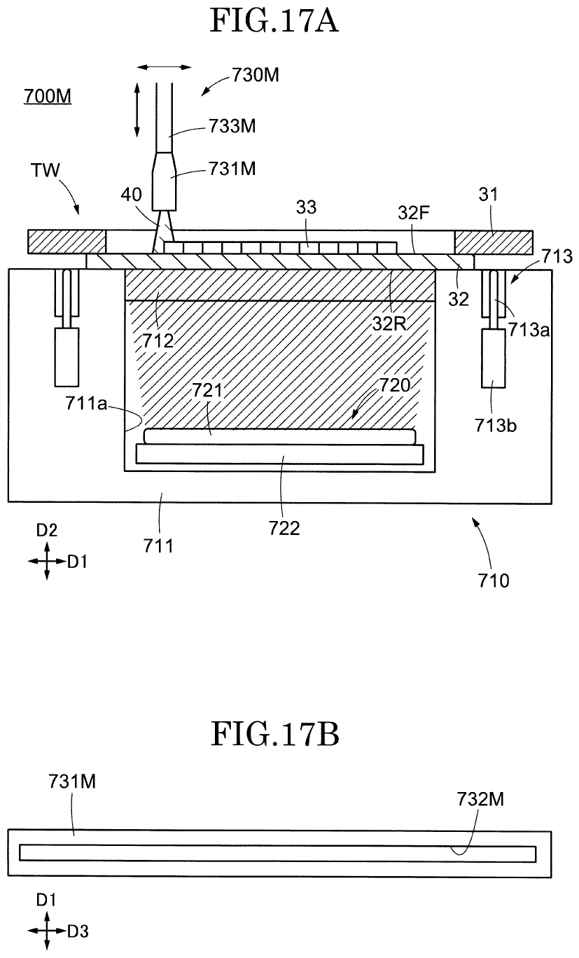

FIG. 17A is a diagram showing a state in which the UV light 50 is irradiated from the light source unit 720 in a UV light irradiation unit 700M according to an embodiment of the present disclosure. FIG. 17B is a bottom view of the head portion 731M of the gas supply unit 730M according to an embodiment of the present disclosure. In the UV light irradiation unit 700M of the present embodiment, the inert gas 40 is supplied from the gas supply unit 730M, which is configured with the slit nozzle. The gas supply unit 730M includes the head portion 731M, a gas discharge portion 732M, and a gas supply pipe 733M.

The head portion 731M is supplied with the inert gas 40 via the gas supply pipe 733M. The inert gas 40 supplied to the head portion 731M is injected from the gas discharge portion 732M toward the adhesive tape 32. The gas supply unit 730M forms the slit nozzle with the head portion 731M and the gas discharge portion 732M. Specifically, as shown in FIG. 17B, the head portion 731M is composed of an elongated member having a longitudinal direction (direction D3 in FIG. 17B), and the gas discharge portion 732M, which is a slit-shaped opening, is provided on the lower surface (the surface facing the adhesive tape 32). The inert gas 40 supplied inside the head portion 731M is injected linearly from the slit-shaped gas discharge portion 732M.

In the present embodiment, the gas supply unit 730M is configured to be movable in a direction (direction D1 in FIG. 17A and FIG. 17B) perpendicular to the longitudinal direction (direction D3). That is, the UV light irradiation unit 700M can supply the inert gas 40 over the entire first surface 32F of the adhesive tape 32 by injecting the inert gas 40 while moving the gas supply unit 730M in the left-right direction (horizontal direction, direction D1). In addition, the gas supply unit 730M is also configured to be movable in the up-down direction (vertical direction, direction D2) and moves back and forth between the standby position and the processing position, similar to the first embodiment.

Furthermore, the example shown in FIG. 17A shows the case in which the light source 721 is a surface light source, but the present disclosure is not limited to this example, and the light source can also be a linear light source.

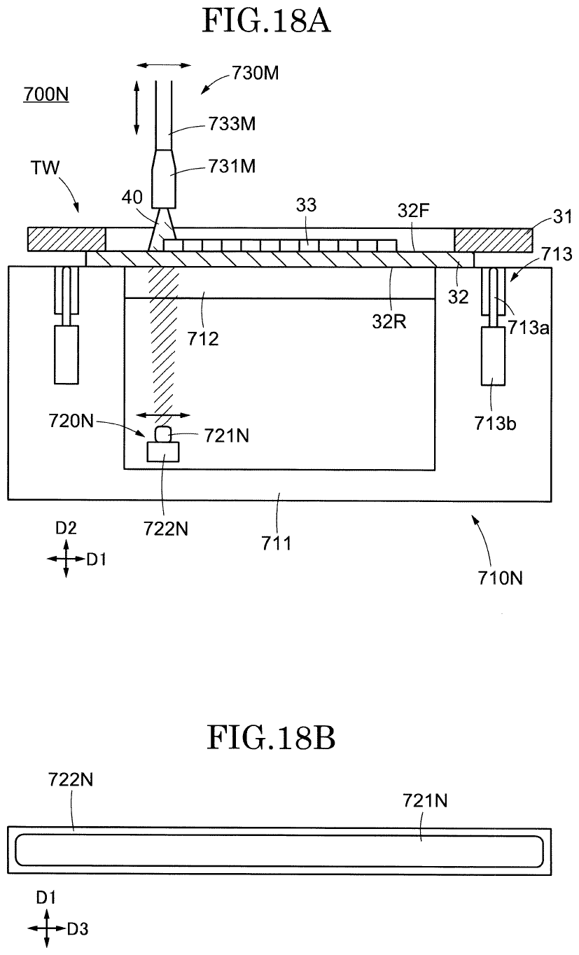

FIG. 18A is a diagram showing a state in which the UV light 50 is irradiated from a light source unit 720N in a UV light irradiation unit 700N according to an embodiment of the present disclosure. FIG. 18B is a top view of the light source unit 720N according to an embodiment of the present disclosure. In the example shown in FIG. 18, the configuration of the gas supply unit 730M is as described with reference to FIG. 17A and FIG. 17B, so a detailed description is omitted. In the example shown in FIG. 18A, the light source unit 720N includes a light source 721N, which is a linear light source, and a light source drive portion 722N that drives the light source 721N.

The light source 721N is composed of a linear light source having a longitudinal direction (direction D3 in FIG. 18B), and lighting control (control of light emission/non-light emission) is performed by the light source drive portion 722N arranged below. In the present embodiment, an LED that emits UV light is used as the light source 721N. However, the present disclosure is not limited to this example, and the light source 721N may be a UV lamp that emits UV light.

In the example shown in FIG. 18A, the light source unit 720N is configured to be movable in a direction (direction D1 in FIG. 18A and FIG. 18B) perpendicular to the longitudinal direction (direction D3). That is, a UV light irradiation unit 700N can irradiate UV light onto the second surface 32R of the adhesive tape 32 while moving the light source unit 720N in the left-right direction (horizontal direction, direction D1). In the example shown in FIG. 18A, it is desirable for the light source unit 720N and the gas supply unit 730M to move synchronously in the direction D1. That is, it is desirable that the range of the UV light irradiation from the light source unit 720N and the range of the inert gas 40 supply from the gas supply unit 730M overlap. As a result, the vicinity of the first surface 32F, which corresponds to the range in the adhesive tape 32 irradiated with UV light, is maintained in an inert atmosphere, thereby effectively suppressing the adverse effects of oxygen inhibition. In addition, by synchronizing the movement of the light source unit 720N and the gas supply unit 730M, the UV light can be selectively irradiated onto the semiconductor chip 33 to be peeled, and an inert atmosphere can be maintained around the semiconductor chip 33. In this case, the gas supply unit 730M only needs to supply the inert gas 40 concentrated around the desired semiconductor chip 33, thereby reducing the consumption of the inert gas 40.

Although the example using the gas supply unit 730M including a slit nozzle was shown in FIG. 17A and FIG. 18A, the present disclosure is not limited to this example, and the gas supply unit 730M may have a configuration in which the inert gas 40 is injected pinpointedly using, for example, a circular nozzle. In this case, it is preferable that the gas supply unit 730M is configured to be movable in both the direction D1 and the direction D3.

Furthermore, although an example in which the gas supply unit 730M moves in the direction D1 was shown in FIG. 17A, the present disclosure is not limited to this example, and the gas supply unit 730M may have a configuration in which the position of the gas supply unit 730M is fixed and the support stage 710 moves in the direction D1. That is, in the present embodiment, it is sufficient to have a configuration if either the gas supply unit or the support stage moves relatively in the left-right direction with respect to the other.

### Eleventh Embodiment

In the present embodiment, an example in which the configuration of the mounting system is different from that of the first embodiment will be described. Specifically, a mounting system 2 of the present embodiment does not include the activation processing unit 500 and the cleaning unit 600 that are included in the pretreatment apparatus 10 of the first embodiment, and a pretreatment apparatus 10a includes only the UV light irradiation unit 700. In the present embodiment, the explanation will focus on the parts of the configuration that are different from the first embodiment. For the same configuration as the mounting system 1 of the first embodiment, redundant explanations may be omitted by using the same reference signs.

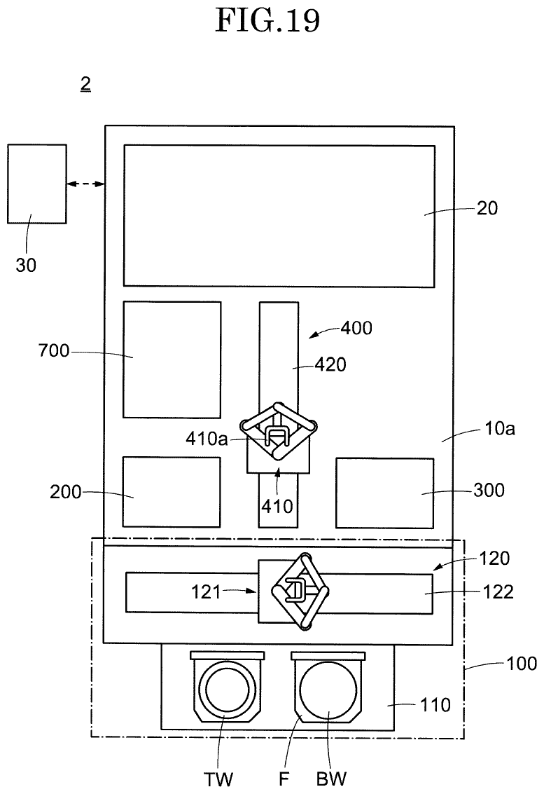

FIG. 19 is a block diagram showing an overall configuration of the mounting system 2 according to an embodiment of the present disclosure. For example, the mounting system 2 is a system for mounting a semiconductor chip with bumps onto the semiconductor wafer. In FIG. 19, the pretreatment apparatus 10a is an apparatus for performing UV light irradiation treatment to reduce or eliminate the adhesive strength by irradiating UV light onto the adhesive tape so that the semiconductor chip to be mounted can be easily picked up from the adhesive tape that supports the semiconductor chip. The bonding apparatus 20 mounts (places, loads, or temporarily bonds) the semiconductor chip received from the pretreatment apparatus 10a onto the mounting substrate.

The pretreatment apparatus 10a of the present embodiment includes the load/unload unit 100, the supply buffer unit 200, the discharge buffer unit 300, the workpiece transport unit 400, and the UV light irradiation unit 700. However, the configuration of the pretreatment apparatus 10a is not limited to this example, and some components shown in FIG. 19 may be omitted, or other components may be added. The specific operations of the load/unload unit 100, the supply buffer unit 200, the discharge buffer unit 300, the workpiece transport unit 400, and the UV light irradiation unit 700 are as described in the first embodiment, so the explanation here is omitted.

According to the present embodiment, similar to the first embodiment, when UV light is irradiated onto the resin film with the semiconductor chip with bumps adhered to reduce the adhesive strength, the influence of oxygen inhibition can be suppressed.

Although the UV light irradiation apparatus according to an embodiment of the present disclosure and the mounting system including the same have been described above with reference to the drawings, the present disclosure is not limited to the embodiments described above and can be modified as appropriate without departing from the spirit of the present disclosure. For example, the addition, deletion, or design change of components as appropriate by those skilled in the art based on each embodiment are also included in the scope of the present disclosure as long as they are provided with the gist of the present disclosure. Furthermore, the configurations according to each of the embodiments described above can be appropriately combined and implemented as long as no contradiction is caused, and technical matters common to the embodiments are included in each configuration even if not explicitly stated.

Further, it is understood that, even if the effect is different from those provided by each of the above-described embodiments, the effect obvious from the description in the specification or easily predicted by persons ordinarily skilled in the art is apparently derived from the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A UV light irradiation apparatus for irradiating UV light onto a resin film with multiple electronic components adhered to a first surface of the resin film, the UV light irradiation apparatus comprising:
a support stage for supporting the resin film;
a gas supply portion for supplying inert gas from a gas discharge portion facing the support stage to the first surface of the resin film; and
a light source portion irradiating UV light onto a second surface of the resin film opposite the first surface.

2. The UV light irradiation apparatus according to claim 1, wherein the UV light is irradiated onto the second surface of the resin film while maintaining an inert atmosphere in the space between the gas discharge portion and the first surface of the resin film.

3. The UV light irradiation apparatus according to claim 1, wherein the gas supply portion is brought closer to the first surface of the resin film while supplying the inert gas to the first surface of the resin film.

4. The UV light irradiation apparatus according to claim 1, wherein the gas discharge portion has a plurality of openings, and
the inert gas is supplied to the first surface of the resin film through the plurality of openings.

5. The UV light irradiation apparatus according to claim 4, wherein the plurality of openings include a first opening located near a center of the gas discharge portion and a second opening located near an outer edge of the gas discharge portion, and
a diameter of the first opening is smaller than a diameter of the second opening.

6. The UV light irradiation apparatus according to claim 4, wherein the plurality of openings include a plurality of first openings located near a center of the gas discharge portion and a plurality of second openings located near an outer edge of the gas discharge portion, and
an arrangement density of the plurality of first openings is smaller than an arrangement density of the plurality of second openings.

7. The UV light irradiation apparatus according to claim 1, wherein the support stage is disposed facing the gas discharge portion and comprises a light-transmissive member transmitting the UV light, and
the light-transmissive member has a surface facing the gas discharge portion and is curved toward the gas discharge portion.

8. The UV light irradiation apparatus according to claim 1, wherein the support stage has an elevating wall movable in a vertical direction, and
when the UV light is irradiated onto the second surface of the resin film, the elevating wall surrounds the lateral sides of the space between the gas discharge portion and the first surface of the resin film.

9. The UV light irradiation apparatus according to claim 1, wherein the gas supply portion has a side wall surrounding the gas discharge portion, and
when the UV light is irradiated onto the second surface of the resin film, the side wall surrounds the lateral sides of the space between the gas discharge portion and the first surface of the resin film.

10. The UV light irradiation apparatus according to claim 1, wherein the gas supply portion has a sealing member disposed facing the support stage so as to surround the gas discharge portion.

11. The UV light irradiation apparatus according to claim 1, wherein the UV light is irradiated onto the second surface of the resin film while the first surface of the resin film is expanded.

12. The UV light irradiation apparatus according to claim 1, wherein the support stage is positioned opposite the gas discharge portion and includes a light-transmissive member transmitting the UV light,
the light-transmissive member is configured to be movable in a vertical direction, and
the UV light is irradiated onto the second surface of the resin film while the first surface of the resin film is expanded by pressing the second surface of the resin film with the light-transmissive member.

13. A mounting system comprising a pretreatment apparatus including the UV light irradiation apparatus according to claim 1, and a bonding apparatus mounting an electronic component received from the pretreatment apparatus onto a substrate.
